(19) United States
(12) Patent Application Publication
(10) Pub. No.: US 2025/0071967 A1
(43) Pub. Date: Feb. 27, 2025

(54) SEMICONDUCTOR DEVICE

(71) Applicant: Samsung Electronics Co., Ltd., Suwon-si (KR)

(72) Inventors: Sohyun Park, Suwon-si (KR); Inwoo Kim, Suwon-si (KR); Kiseok Lee, Suwon-si (KR)

(21) Appl. No.: 18/673,537

(22) Filed: May 24, 2024

(30) Foreign Application Priority Data
Aug. 22, 2023 (KR) 10-2023-0110033

(51) Int. Cl. H10B 12/00

(52) U.S. Cl. CPC H10B 12/0335; H10B 12/315; H10B 12/50

(57) ABSTRACT

A semiconductor device includes a semiconductor substrate, a plurality of contact plugs spaced apart from each other on the semiconductor substrate, a plurality of first landing pads spaced apart from each other on the plurality of contact plugs, a landing insulating layer surrounding upper sidewalls of the plurality of first landing pads and covering upper portions of the plurality of first landing pads, a stopper insulating layer disposed on the landing insulating layer, and a plurality of second landing pads spaced apart from each other on the plurality of first landing pads, passing through the stopper insulating layer, and buried in landing opening holes formed in the landing insulating layer, the plurality of second landing pads being electrically and respectively connected to the plurality of first landing pads.

### CROSS-REFERENCE TO RELATED APPLICATION

This application is based on and claims priority under 35 U.S.C. § 119 to Korean Patent Application No. 10-2023-0110033, filed on Aug. 22, 2023, in the Korean Intellectual Property Office, the disclosure of which is incorporated by reference herein in its entirety.

### BACKGROUND

The inventive concept relates to a semiconductor device, and more particularly, to a semiconductor device including a vertical connection structure of contact plugs and landing pads.

Semiconductor devices may include conductive patterns and contact plugs on semiconductor substrates. As semiconductor devices become more highly integrated, distances between the conductive patterns and/or distances between the contact plugs have been gradually reduced. In addition, the semiconductor devices may include landing pads vertically connected to the contact plugs on the semiconductor substrates.

### SUMMARY

The inventive concept provides a semiconductor device capable of reliably establishing a vertical connection structure of contact plugs and landing pads and reducing parasitic capacitance between the landing pads.

According to an aspect of the inventive concept, there is provided a semiconductor device including a semiconductor substrate, a plurality of contact plugs spaced apart from each other on the semiconductor substrate, a plurality of first landing pads spaced apart from each other on the plurality of contact plugs, a landing insulating layer surrounding upper sidewalls of the plurality of first landing pads and covering upper portions of the plurality of first landing pads, a stopper insulating layer disposed on the landing insulating layer, and a plurality of second landing pads spaced apart from each other on the plurality of first landing pads, passing through the stopper insulating layer, and buried in landing opening holes formed in the landing insulating layer, the plurality of second landing pads being electrically and respectively connected to the plurality of first landing pads.

According to an aspect of the inventive concept, there is provided a semiconductor device including a semiconductor substrate, a plurality of contact plugs spaced apart from each other on the semiconductor substrate in a first horizontal direction and a second horizontal direction perpendicular to the first horizontal direction, a plurality of first landing pads spaced apart from each other on the plurality of contact plugs in the first horizontal direction and the second horizontal direction, a plurality of fence insulating layers arranged on the semiconductor substrate, wherein each of the fence insulating layers extends lengthwise in the first horizontal direction and the plurality of fence insulating layers are spaced apart from each other in the second horizontal direction, a landing insulating layer disposed on the plurality of fence insulating layers, surrounding upper sidewalls of the plurality of first landing pads, and covering upper portions of the plurality of first landing pads, a stopper insulating layer disposed on the landing insulating layer, and a plurality of second landing pads spaced apart from each other on the plurality of first landing pads in the first horizontal direction and the second horizontal direction, passing through the stopper insulating layer, and buried in landing opening holes formed in the landing insulating layer, the plurality of second landing pads being electrically and respectively connected to the plurality of first landing pads.

According to another aspect of the inventive concept, there is provided a semiconductor device including a semiconductor substrate including a cell region and an interface region surrounding the cell region, wherein the cell region includes a plurality of first contact plugs spaced apart from each other on the semiconductor substrate, a plurality of first landing pads arranged on the plurality of first contact plugs, a landing insulating layer surrounding upper sidewalls of the plurality of first landing pads and covering upper portions of the plurality of first landing pads, a stopper insulating layer disposed on the landing insulating layer, and a plurality of second landing pads spaced apart from each other on the plurality of first landing pads, passing through the stopper insulating layer, and buried in landing opening holes formed in the landing insulating layer, the plurality of second landing pads being electrically and respectively connected to the plurality of first landing pads.

The interface region includes a plurality of second contact plugs, a plurality of interface insulating capping patterns formed above the plurality of second contact plugs, a plurality of buried patterns formed on the interface insulating capping patterns, and an interface insulating layer insulating the plurality of buried patterns from each other on the interface insulating capping patterns.

### BRIEF DESCRIPTION OF THE DRAWINGS

Embodiments will be more clearly understood from the following detailed description taken in conjunction with the accompanying drawings in which:

FIG. 1 is a plan view illustrating a semiconductor device according to an embodiment;

FIG. 2 is a schematic layout view illustrating components of a cell region of a semiconductor device according to an embodiment;

FIG. 3A is a cross-sectional view of a semiconductor device according to an embodiment;

FIG. 3B is an enlarged view of a portion of FIG. 3A;

FIG. 4A is a cross-sectional view of a semiconductor device according to an embodiment;

FIG. 4B is an enlarged view of a portion of FIG. 4A;

FIGS. 5A, 5B, and 6 to 15 are views for explaining a method of manufacturing a semiconductor device of FIGS. 3A and 4A;

FIGS. 16 and 17 are cross-sectional views illustrating a semiconductor device including a storage electrode, according to an embodiment;

FIGS. 18 to 24 are cross-sectional views illustrating a semiconductor device including a first landing pad and a second landing pad, according to an embodiment;

FIGS. 25 to 27 are cross-sectional views illustrating a semiconductor device including a cell region, an interface region, and a core region, according to an embodiment;

FIGS. 28 to 30 are cross-sectional views illustrating a semiconductor device including a cell region, an interface region, and a core region, according to an embodiment;

FIGS. 31 to 33 are cross-sectional views illustrating a semiconductor device including a cell region, an interface region, and a core region, according to an embodiment; and

FIGS. 34 to 36 are cross-sectional views illustrating a semiconductor device including a cell region, an interface region, and a core region, according to an embodiment.

### DETAILED DESCRIPTION OF THE EMBODIMENTS

Hereinafter, an embodiment is described in detail with reference to the accompanying drawings. The inventive concept may be made by any one of embodiments described below or by combining one or more embodiments. Accordingly, the inventive concept should not be construed as being limited to one embodiment.

As used herein, the singular forms include the plural forms as well, unless the context clearly indicates otherwise. In this specification, the drawings are exaggerated to more clearly describe the inventive concept.

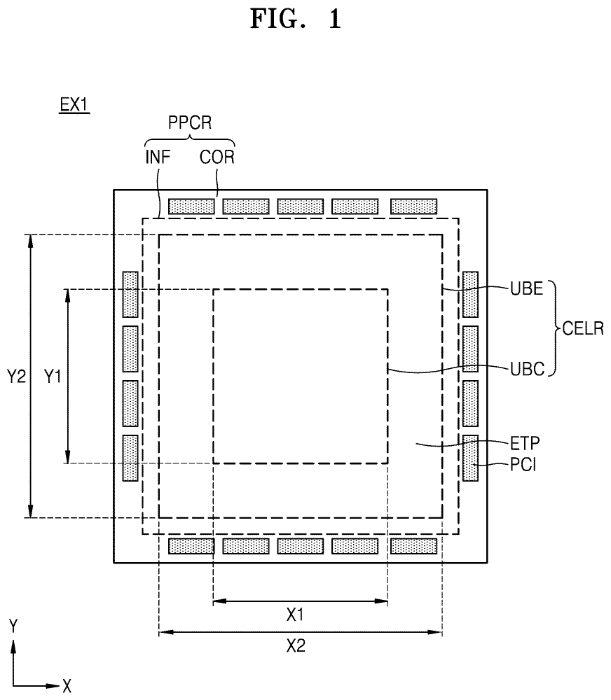

FIG. 1 is a plan view illustrating a semiconductor device EX1 according to an embodiment.

Specifically, the semiconductor device EX1 may include a cell region CELR and a peripheral circuit region PPCR surrounding the cell region CELR in a plan view. The cell region CELR may include a cell center region UBC and a cell edge region UBE surrounding the cell center region UBC in a plan view.

The cell edge region UBE may be located on one side of the cell center region UBC in a first horizontal direction (X direction). The cell edge region UBE may be located on one side of the cell center region UBC in a second horizontal direction (Y direction). The cell center region UBC and cell edge region UBE may also be referred to as a unit block center region and a unit block edge region, respectively.

The cell region CELR may have a length X2 and a length Y2 in the first horizontal direction (X direction) and the second horizontal direction (Y direction), respectively. The length X2 and the length Y2 may be several millimeters to tens of millimeters. The cell center region UBC of the cell region CELR may have a length X1 and a length Y1 in the first horizontal direction (X direction) and the second horizontal direction (Y direction), respectively. In the cell region CELR, a region other than the cell center region UBC may be included in the cell edge region UBE.

In some embodiments, the length of the cell edge region UBE may be 5% or less of the length of the cell region CELR. For example, the cell edge region UBE may have a length difference (X2−X1) that is obtained by subtracting the length X1 of the cell center region UBC in the first horizontal direction (X direction) from the length X2 of the cell region CELR in the first horizontal direction (X direction). The length difference (X2−X1) may be less than or equal to 5% of the length X1. The cell edge region UBE may have a length difference (Y2−Y1) that is obtained by subtracting the length Y1 of the cell center region UBC in the second horizontal direction (Y direction) from the length Y2 of the cell region CELR in the second horizontal direction (Y direction). The length difference (Y2−Y1) may be less than or equal to 5% of the length Y1.

The peripheral circuit region PPCR may include an interface region INF surrounding the cell region CELR and a core region COR surrounding the interface region INF. A peripheral circuit PCI may be arranged in the core region COR.

The semiconductor device EX1 may include a memory element. Accordingly, the cell region CELR described above may include a memory cell region. The memory element may include a volatile memory element, such as dynamic random access memory (DRAM).

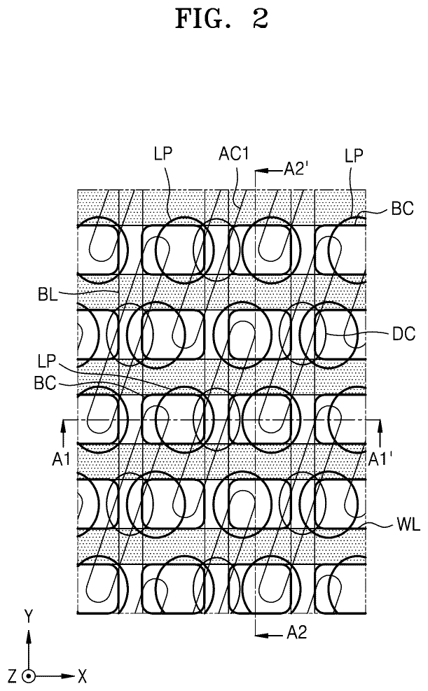

FIG. 2 is a schematic layout view illustrating components of a cell region of a semiconductor device according to an embodiment.

Specifically, FIG. 2 may be a diagram for illustrating components of the cell center region UBC of the semiconductor device EX1 of FIG. 1. The semiconductor device EX1 may include a plurality of active regions AC1. The plurality of active regions AC1 may be arranged in a diagonal direction with respect to the first horizontal direction (X direction) and the second horizontal direction (Y direction).

A plurality of word lines WL may extend parallel to each other in the first horizontal direction (X direction) across the plurality of active regions AC1. Above the plurality of word lines WL, a plurality of bit lines BL may extend parallel to each other in the second horizontal direction (Y direction) intersecting with the first horizontal direction (X direction). The plurality of bit lines BL may be connected to the plurality of active regions AC1 through direct contacts DC.

A plurality of buried contact plugs BC may be formed between two neighboring bit lines BL among the plurality of bit lines BL. Each of the buried contact plugs BC may also be referred to as a buried contact. In some embodiments, the plurality of buried contact plugs BC may be arranged in a line in each of the first horizontal direction (X direction) and the second horizontal direction (Y direction).

A plurality of landing pads LP may be formed above the plurality of buried contact plugs BC. Each of the landing pads LP may include a conductive material. The plurality of buried contact plugs BC and the plurality of landing pads LP may connect a storage electrode (or a lower electrode, not shown) of a capacitor formed on upper portions of the plurality of bit lines BL to the active regions AC1. At least a portion of each of the plurality of landing pads LP may vertically overlap the buried contact plug BC.

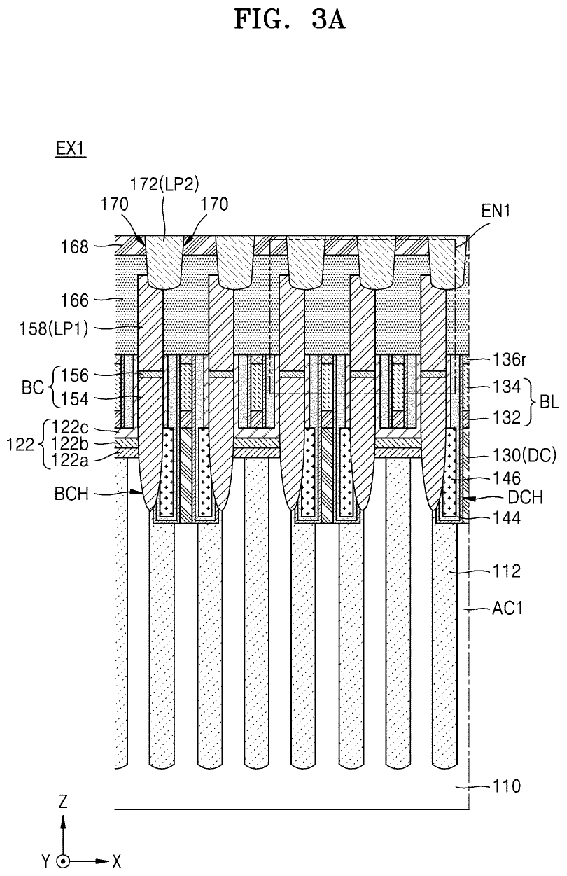

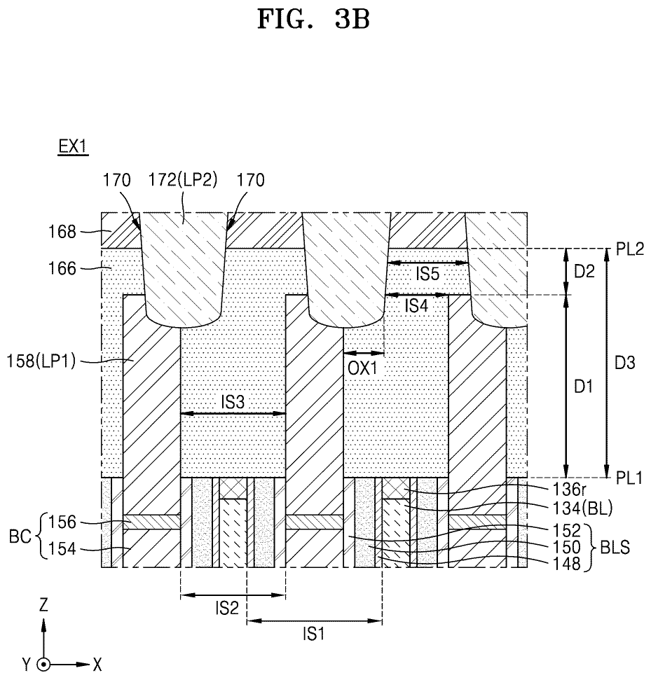

FIG. 3A is a cross-sectional view of the semiconductor device EX1 according to an embodiment and FIG. 3B is an enlarged view of a portion of FIG. 3A.

Specifically, FIG. 3A is a cross-sectional view of the semiconductor device EX1 of FIG. 2 taken along the first horizontal direction (X direction), that is, along line A1-A1′. FIG. 3B is an enlarged view of region EN1 of FIG. 3A. The descriptions given with reference to FIG. 2 are briefly given or omitted when describing FIGS. 3A and 3B.

The semiconductor device EX1 includes a semiconductor substrate 110 in which a plurality of active regions AC1 are defined by device isolation layers 112. The device isolation layers 112 may be formed in the semiconductor substrate 110. Each of the device isolation layers 112 may include or may be a silicon oxide film.

The semiconductor substrate 110 may include or may be formed of silicon, for example, single crystalline silicon, polycrystalline silicon, or amorphous silicon. In some embodiments, the semiconductor substrate 110 may include or may be formed of at least one selected from among Ge, SiGe, SiC, GaAs, InAs, and InP.

In some embodiments, the semiconductor substrate 110 may include conductive regions, for example, wells doped with impurities or structures doped with impurities. The device isolation layer 112 may include or may be an oxide film, a nitride film, or a combination thereof.

A buffer layer 122 is formed on the semiconductor substrate 110. The buffer layer 122 may be formed on the upper surfaces of the plurality of active regions AC1 and the upper surfaces of the device isolation layers 112. The buffer layer 122 may include or may be formed of at least one of a silicon oxide film and a silicon nitride film. In some embodiments, the buffer layer 122 may include a first silicon oxide film 122a, a second silicon oxide film 122b, and a silicon nitride film 122c, which are sequentially formed on the semiconductor substrate 110.

In some embodiments, the first silicon oxide film 122a of the buffer layer 122 may be omitted depending on a manufacturing process. In this case, the buffer layer 122 may include or may be formed of the second silicon oxide film 122b and the silicon nitride film 122c. In some embodiments, the first silicon oxide film 122a and the second silicon oxide film 122b of the buffer layer 122 may be omitted depending on a manufacturing process. In this case, the buffer layer 122 may include or may be the silicon nitride film 122c.

The plurality of bit lines BL are formed on the buffer layer 122 and spaced apart from each other in the first horizontal direction (X direction). In some embodiments, the bit line BL may be formed on a silicon oxide film or a silicon nitride film depending on the material that constitutes the buffer layer 122.

The plurality of bit lines BL may be respectively connected to the active regions AC1 via direct contacts DC. The direct contact DC may be provided in plurality. The plurality of direct contacts DC may be spaced apart from each other in the first horizontal direction (X direction).

The direct contacts DC are formed in some of the plurality of active regions AC1. The direct contacts DC are respectively buried in direct contact holes DCH through which the active regions AC1 of the semiconductor substrate 110 are exposed. The lower ends of the direct contacts DC may be at a lower level than the upper surface of the semiconductor substrate 110 so that the lower ends of the direct contacts DC are buried in the semiconductor substrate 110 to increase a contact surface between the direct contacts DC and the active regions AC1.

In some embodiments, each of the direct contacts DC may include a lower conductive pattern 130. The lower conductive pattern 130 may include a polysilicon film doped with impurities, such as boron (B), arsenic (As), and phosphorus (P). In some embodiments, the lower conductive pattern 130 may include Si, Ge, W, WN, Co, Ni, Al, Mo, Ru, Ti, TiN, Ta, TaN, Cu, or a combination thereof.

Each of the plurality of bit lines BL may include a middle conductive pattern 132 and an upper conductive pattern 134, which are sequentially formed on the direct contact DC. An insulating capping pattern 136r is formed on each of the plurality of bit lines BL. The insulating capping pattern 136r may be disposed on the upper conductive pattern 134. The upper surface of the lower conductive pattern 130 and the upper surface of the direct contact DC may be on the same plane.

FIG. 3A illustrates that the plurality of bit lines BL has a double conductive layer structure including the middle conductive pattern 132 and the upper conductive pattern 134, but the inventive concept is not limited thereto.

For example, the plurality of bit lines BL may be described as including the lower conductive pattern 130, the middle conductive pattern 132, and the upper conductive pattern 134. For example, the upper and middle conductive patterns 134 and 132 of each of the bit lines BL may extend in the second horizontal direction (Y direction), and at locations where each bit line BL and a corresponding active region AC1 are connected with other, the lower conductive pattern 130 is connected to the middle conductive pattern 132. The lower conductive pattern 130 may fill a direct contact hole DCH exposing the corresponding active region AC1 of the semiconductor substrate 110. The plurality of bit lines BL may have a single conductive pattern or a stacked structure of a plurality of conductive patterns having a quadruple conductive pattern or more.

In some embodiments, the middle conductive pattern 132 may include a barrier metal layer. In some embodiments, the upper conductive pattern 134 may include a metal layer. In some embodiments, the middle conductive pattern 132 and the upper conductive pattern 134 may each include a film including Ti, TiN, TiSiN, tungsten (W), WN, tungsten silicide (WSix), tungsten silicon nitride (WSixNy), ruthenium (Ru), or a combination thereof.

For example, the middle conductive pattern 132 may include a TiN film and/or a TiSiN film and the upper conductive pattern 134 may include tungsten (W). In some embodiments, the insulating capping pattern 136r may include or may be a silicon nitride film.

The plurality of buried contact plugs BC may be disposed on the semiconductor substrate 110. Each of the buried contact plugs BC may be referred to as a buried contact or contact plug. The plurality of buried contact plugs BC may be spaced apart from each other in the first horizontal direction (X direction). Each of the buried contact plugs BC may have a pillar shape extending in the vertical direction (Z direction) in a space between the plurality of bit lines BL. The plurality of buried contact plugs BC may be in contact with the active regions AC1. The term “contact,” as used herein, refers to a direct connection (i.e., physical touching) unless the context indicates otherwise.

The buried contact plugs BC are respectively buried in buried contact holes BCH through which the active regions AC1 of the semiconductor substrate 110 are exposed. The lower ends of the buried contact plugs BC may be at a lower level than the upper surface of the semiconductor substrate 110 so that the lower ends of the buried contact plugs BC are buried in the semiconductor substrate 110.

Each of the buried contact plugs BC may include a metal, a conductive metal nitride, a semiconductor material doped with impurities such as boron (B), arsenic (As), and phosphorus (P), or a combination thereof. In some embodiments, the buried contact plug BC may include a plug conductive layer 154 and a plug metal silicide layer 156.

In some embodiments, the plug conductive layer 154 may include a semiconductor material doped with impurities, such as boron (B), arsenic (As), and phosphorus (P). In some embodiments, the plug metal silicide layer 156 may include cobalt silicide, nickel silicide, or manganese silicide.

One direct contact DC and each of a pair of buried contact plugs BC facing each other with the one direct contact DC therebetween may be connected to different active regions AC1 among the plurality of active regions AC1. For example, in each active region AC1, one direct contact DC and a pair of buried contact plugs BC may be formed. The one direct contact DC may be disposed in a space between the pair of buried contact plugs BC.

The semiconductor device EX1 may include first inner spacers 144 and gap-fill insulating patterns 146, which are arranged between the plurality of direct contacts DC and the plurality of buried contact plugs BC. Each of the first inner spacers 144 may be formed on the sidewall of the direct contact DC and the bottom of the direct contact hole DCH. In some embodiments, the first inner spacer 144 may include a silicon nitride layer.

Each of the gap-fill insulating patterns 146 may be formed on the lower sidewall of the buried contact plug BC and the sidewall of the first inner spacer 144. In some embodiments, the gap-fill insulating pattern 146 may include a silicon oxide layer.

As shown in FIG. 3B, the semiconductor device EX1 may include a plurality of spacer structures BLS arranged between the bit lines BL and the buried contact plugs BC. Each of the spacer structures BLS may include a second inner spacer 148, a middle spacer 150, and an outer spacer 152. The middle spacer 150 may be located between the second inner spacer 148 and the outer spacer 152. The second inner spacer 148 may include the same material as the first inner spacer 144. In some embodiments, the middle spacer 150 may include a silicon oxide layer. In some embodiments, the outer spacer 152 may include a silicon nitride layer.

A plurality of first landing pads LP1 may be formed on the upper portions of the plurality of buried contact plugs BC. The plurality of first landing pads LP1 may be arranged on the plurality of buried contact plugs BC and spaced apart from each other in the first horizontal direction (X direction). Each of the first landing pads LP1 protrudes from the surface of the insulating capping pattern 136r above the bit line BL.

The first landing pad LP1 may be connected to the buried contact plug BC. Each of the first landing pads LP1 may include a lower conductive pattern 158. The lower conductive pattern 158 may include doped polysilicon, metal, metal silicide, conductive metal nitride, or a combination thereof. In some embodiments, the lower conductive pattern 158 may include tungsten (W).

The semiconductor device EX1 may include a landing insulating layer 166 that surrounds upper sidewalls of the plurality of first landing pads LP1 and covers the upper portions of the plurality of first landing pads LP1. For example, the landing insulating layer 166 may contact an upper sidewall and a top surface of each of the first landing pads LP1. The landing insulating layer 166 may fill separation spaces around the plurality of first landing pads LP1. The plurality of first landing pads LP1 may be electrically insulated from each other by the landing insulating layer 166.

In some embodiments, the landing insulating layer 166 may include or may be formed of a material having lower permittivity than the silicon nitride layer. In some embodiments, the landing insulating layer 166 may include or may be a silicon oxide film or a silicon oxycarbide (SiOC) film.

A stopper insulating layer 168 may be disposed on the landing insulating layer 166. In some embodiments, the stopper insulating layer 168 may include a silicon nitride layer. A plurality of second landing pads LP2 are arranged on the plurality of first landing pads LP1 and electrically connected to the first landing pads LP1.

Each of the second landing pads LP2 may include an upper conductive pattern 172. The upper conductive pattern 172 may include doped polysilicon, metal, metal silicide, conductive metal nitride, or a combination thereof. In some embodiments, the upper conductive pattern 172 may include or may be formed of tungsten (W).

A plurality of second landing pads LP2 may be arranged on the first landing pads LP1 and spaced apart from each other in the first horizontal direction (X direction). Each of the second landing pads LP2 may pass through the stopper insulating layer 168 and may be buried in a landing opening hole 170 formed in the landing insulating layer 166. For example, the landing opening hole 170 may penetrate the stopper insulating layer 168 and the landing insulating layer 166 to expose a corresponding first landing pad LP1. In the forming of the landing opening hole 170, an upper portion of the corresponding first landing pad LP1 may be partially removed. Accordingly, the second landing pads LP2 may be electrically and respectively connected to the first landing pads LP1. The second landing pad LP2 and the first landing pad LP1 may constitute the landing pad LP of FIG. 2.

Here, arrangements and relationships between the bit line BL, the buried contact plug BC, the first landing pad LP1, the second landing pad LP2, and the landing insulating layer 166 are described with reference to FIG. 3B.

In more detail, the plurality of bit lines BL are spaced apart from each other by a first separation distance IS1 in the first horizontal direction (X direction). The plurality of buried contact plugs BC are spaced apart from each other by a second separation distance IS2 in the first horizontal direction (X direction). The buried contact plug BC may be located in a space between two adjacent bit lines BL in the first horizontal direction (X direction).

The plurality of first landing pads LP1 may protrude from a first horizontal line PL1 on the upper surface of the insulating capping pattern 136r above the bit line BL. The first landing pads LP1 protrude, by a first vertical distance D1, from the first horizontal line PL1 on the upper surface of the insulating capping pattern 136r above the bit line BL. A vertical short circuit between the second landing pad LP2 and the buried contact plug BC below the second landing pad LP2 may be suppressed by the first vertical distance D1.

The plurality of first landing pads LP1 are spaced apart from each other by a third separation distance IS3 in the first horizontal direction (X direction). The occurrence of a horizontal short circuit between two neighboring first landing pads LP1 may be suppressed by the third separation distance IS3.

The landing insulating layer 166 may be placed between a first horizontal line PL1 located at a first vertical distance D1 from the upper surface of the first landing pad LP1 in a direction toward the buried contact plug BC and a second horizontal line PL2 located at a second vertical distance D2 from the upper surface of the first landing pad LP1 in a direction toward the stopper insulating layer 168. For example, the landing insulating layer 166 may fill the space between a bottom surface of the stopper insulating layer 168 and top surfaces of the insulating capping patterns 136r. The vertical distance between the first horizontal line PL1 and the second horizontal line PL2 may be equal to a third vertical distance D3.

As described above, the landing insulating layer 166 may include or may be formed of a material having lower permittivity than the silicon nitride layer, for example, may include or may be a silicon oxide film or a silicon oxycarbide (SiOC) film. In this case, the parasitic capacitance between the plurality of first landing pads LP1 or second landing pads LP2 may be reduced.

The plurality of second landing pads LP2 may pass through the stopper insulating layer 168 and may be buried in the landing opening holes 170 in a portion of the landing insulating layer 166. After the landing insulating layer 166 and the stopper insulating layer 168 are formed, the landing opening hole 170 may be formed using a photoetching process. The plurality of second landing pads LP2 may be spaced apart from each other by a fifth separation distance IS5. The occurrence of a horizontal short circuit between two neighboring second landing pads LP2 may be suppressed by the fifth separation distance IS5. The second landing pad LP2 may be formed by filling the landing opening hole 170 with a conductive layer for the second landing pad LP2. Accordingly, the second landing pads LP2 may be reliably formed during a manufacturing process.

The second landing pad LP2 may be horizontally shifted, by a first offset distance OX1, from the first landing pad LP1 in the first horizontal direction (X direction). A portion of the second landing pad LP2 may not vertically overlap the first landing pad LP1. Accordingly, the second landing pad LP2 and the first landing pad LP1 may be spaced apart from each other by a fourth separation distance IS4, which is less than the fifth separation distance IS5. For example, a vertical line symmetrically dividing the second landing pad LP2 may be shifted by an offset distance in the first horizontal direction (X direction) from a vertical line symmetrically dividing the first landing pad LP1. The offset distance may be the same as the first offset distance OX1.

Even if the fourth separation distance IS4 is less than the fifth separation distance IS5, the occurrence of a horizontal short circuit between a plurality of adjacent second landing pads LP2 or between a plurality of adjacent first landing pads LP1 may be suppressed. The second landing pad LP2 may be electrically connected to the first landing pad LP1 in a vertical direction.

The semiconductor device EX1 described above may reliably establish a vertical connection structure of the buried contact plugs BC and the first and second landing pads LP1 and LP2 and may also reduce parasitic capacitance between the first and second landing pads LP1 and LP2.

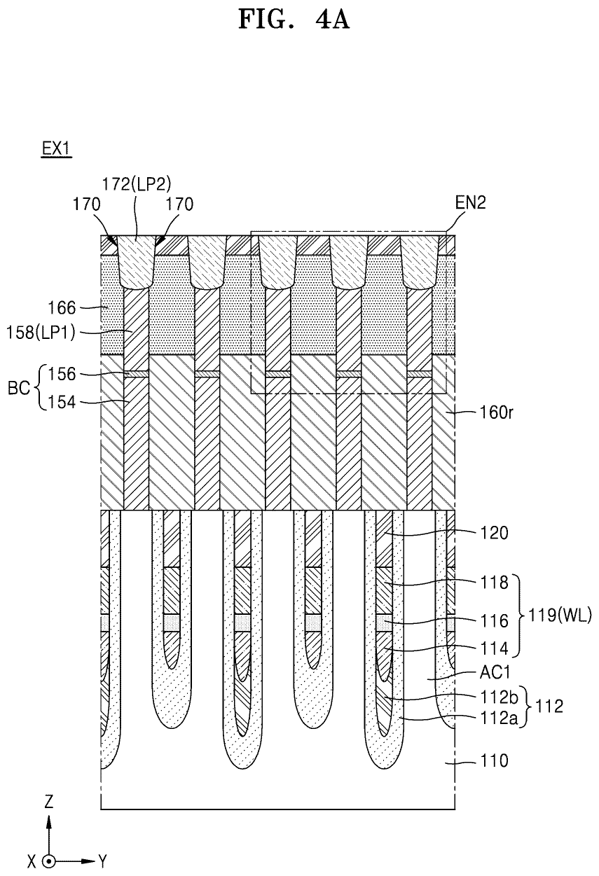

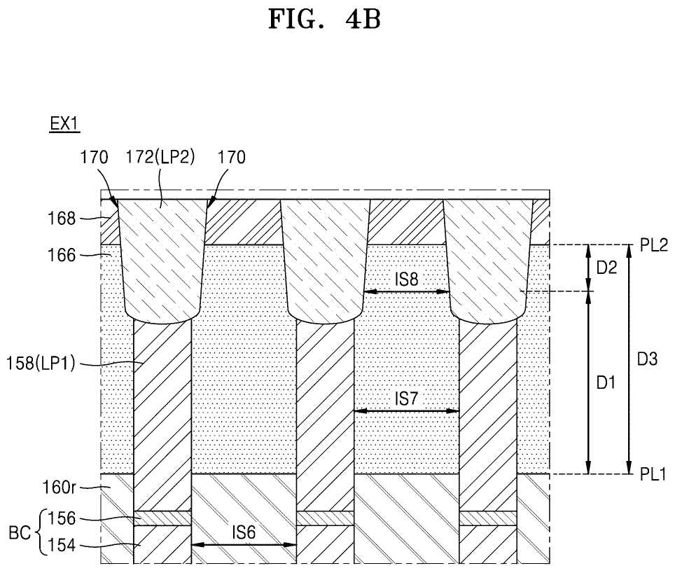

FIG. 4A is a cross-sectional view of the semiconductor device EX1 according to an embodiment and FIG. 4B is an enlarged view of a portion of FIG. 4A.

Specifically, FIG. 4A is a cross-sectional view of the semiconductor device EX1 of FIG. 2 taken in the second horizontal direction (Y direction), that is, taken along line A2-A2′. FIG. 4B is an enlarged view of region EN2 of FIG. 4A. The descriptions given with reference to FIGS. 2, 3A, and 3B are briefly given or omitted when describing FIGS. 4A and 4B.

The semiconductor device EX1 includes a semiconductor substrate 110 in which a plurality of active regions AC1 are defined by a plurality of device isolation layers 112. The device isolation layers 112 may be formed in the semiconductor substrate 110. Each of the device isolation layers 112 may include a silicon oxide film 112a and a silicon nitride film 112b.

A plurality of word lines 119 (WL of FIG. 2) may be arranged inside the device isolation layers 112. The word lines 119 may correspond to the word lines WL of FIG. 2. The plurality of word lines 119 are spaced apart from each other in the second horizontal direction (Y direction). The word lines 119 may be buried in a word line trench formed in the semiconductor substrate 110.

Each of the word lines 119 may include gate conductive layers 114, 116, and 118. The gate conductive layers 114, 116, and 118 may include a lower gate conductive layer, a middle gate conductive layer, and an upper gate conductive layer. Hereinafter, the gate conductive layer 114 may be referred to as a lower gate conductive layer 114, the gate conductive layer 116 may be referred to as a middle gate conductive layer 116, and the gate conductive layer 118 may be referred to as an upper gate conductive layer 118. A gate dielectric film (not shown) may be formed below the gate conductive layers 114, 116, and 118, for example, the lower gate conductive layer 114.

The gate dielectric film may include at least one selected from among a silicon oxide film, a silicon nitride film, a silicon oxynitride film, an oxide/nitride/oxide (ONO) film, and a high-k dielectric film having a higher dielectric constant than the silicon oxide film. The gate conductive layers 114, 116, and 118 may include Ti, TIN, Ta, TaN, W, WN, TiSiN, WSiN, or a combination thereof.

A gate cap layer 120 may be formed on the upper gate conductive layer 118 among the gate conductive layers 114, 116, and 118. In some embodiments, the gate cap layer 120 may include a silicon nitride layer. A plurality of buried contact plugs BC may be formed on a plurality of active regions AC1.

The plurality of buried contact plugs BC may be spaced apart from each other in the second horizontal direction (Y direction). In some embodiments, the buried contact plug BC may include a plug conductive layer 154 and a plug metal silicide layer 156.

A plurality of fence insulating layers 160r are formed on gate cap layers 120 and the device isolation layers 112. The fence insulating layers 160r are spaced apart from each other in the second horizontal direction (Y direction). In some embodiments, each of the fence insulating layers 160r may include or may be formed of a silicon nitride layer. The fence insulating layers 160r may be formed between the plurality of buried contact plugs BC. In an embodiment, each of the plurality of fence insulating layers may extend lengthwise in the first horizontal direction (X direction) along a corresponding word line WL.

A plurality of first landing pads LP1 may be formed on the upper portions of the plurality of buried contact plugs BC. The fence insulating layer 160r may partially cover the lower portions of the first landing pads LP1. The plurality of first landing pads LP1 may be arranged on the plurality of buried contact plugs BC and spaced apart from each other in the second horizontal direction (Y direction). Each of the first landing pads LP1 protrudes from the surface of the fence insulating layer 160r.

The first landing pad LP1 may be connected to the buried contact plug BC. Each of the first landing pads LP1 may include a lower conductive pattern 158. The semiconductor device EX1 may include a landing insulating layer 166 that surrounds upper sidewalls of the plurality of protruding first landing pads LP1 and covers the upper portions of the plurality of first landing pads LP1.

A stopper insulating layer 168 may be disposed on the landing insulating layer 166. A plurality of second landing pads LP2 are arranged on the plurality of first landing pads LP1 and electrically connected to the first landing pads LP1. Each of the second landing pads LP2 may include an upper conductive pattern 172.

A plurality of second landing pads LP2 may be arranged on the first landing pads LP1 and spaced apart from each other in the second horizontal direction (Y direction). Each of the second landing pads LP2 may pass through the stopper insulating layer 168 and may be buried in a landing opening hole 170 formed in the landing insulating layer 166.

Here, arrangements and relationships between the buried contact plug BC, the first landing pad LP1, the second landing pad LP2, and the landing insulating layer 166 are described with reference to FIG. 4B.

In more detail, the plurality of buried contact plugs BC are spaced apart from each other by a sixth separation distance IS6 in the second horizontal direction (Y direction). The buried contact plug BC may be located between two bit lines BL in the second horizontal direction (Y direction).

The plurality of first landing pads LP1 may protrude from a first horizontal line PL1 on the upper surface of the fence insulating layers 160r. The first horizontal line PL1 may be at the same level as the first horizontal line PL1 described in FIG. 3B.

The first landing pads LP1 protrude, by a first vertical distance D1, from the first horizontal line PL1 on the upper surface of the fence insulating layer 160r. A vertical short circuit between the second landing pad LP2 and the buried contact plug BC below the second landing pad LP2 may be suppressed by the first vertical distance D1.

The plurality of first landing pads LP1 are spaced apart from each other by a seventh separation distance IS7 in the second horizontal direction (Y direction). The occurrence of a horizontal short circuit between two neighboring first landing pads LP1 may be suppressed by the seventh separation distance IS7.

The landing insulating layer 166 may be placed between a first horizontal line PL1 located at a first vertical distance D1 from the upper surface of the first landing pad LP1 in a direction toward the buried contact plug BC and a second horizontal line PL2 located at a second vertical distance D2 from the upper surface of the first landing pad LP1 in a direction toward the stopper insulating layer 168. The second horizontal line PL2 may be at the same level as the second horizontal line PL2 described in FIG. 3B. The vertical distance between the first horizontal line PL1 and the second horizontal line PL2 may be equal to a third vertical distance D3.

As described above, the landing insulating layer 166 may include or may be formed of a material having lower permittivity than the silicon nitride layer, for example, may include a silicon oxide film or a silicon oxycarbide (SiOC) film. In this case, the parasitic capacitance between the plurality of first landing pads LP1 or second landing pads LP2 may be reduced.

The plurality of second landing pads LP2 may pass through the stopper insulating layer 168 and may be buried in the landing opening holes 170 in a portion of the landing insulating layer 166. After the landing insulating layer 166 and the stopper insulating layer 168 are formed, the landing opening hole 170 may be formed using a photoetching process. The plurality of second landing pads LP2 may be spaced apart from each other by an eighth separation distance IS8. The occurrence of a horizontal short circuit between two neighboring second landing pads LP2 may be suppressed by the eighth separation distance IS8. The second landing pad LP2 may be formed by filling the landing opening hole 170 with a conductive layer for the second landing pad LP2. Accordingly, the second landing pads LP2 may be reliably formed during a manufacturing process.

The second landing pad LP2 may not be offset from the first landing pad LP1 in the second horizontal direction (Y direction) but may vertically overlap the first landing pad LP1. For example, a vertical line symmetrically dividing the second landing pad LP2 may be vertically aligned with a vertical line symmetrically dividing the first landing pad LP1. The separation distance between the second landing pads LP2 may have the eighth separation distance IS8, which is substantially equal to the seventh separation distance IS7. Accordingly, the occurrence of a horizontal short circuit between a plurality of adjacent second landing pads LP2 or between a plurality of adjacent first landing pads LP1 may be suppressed. The second landing pad LP2 may be electrically connected to the first landing pad LP1 in a vertical direction. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

The semiconductor device EX1 described above may reliably establish a vertical connection structure of the buried contact plugs BC and the first and second landing pads LP1 and LP2 and may also reduce parasitic capacitance between the first and second landing pads LP1 and LP2.

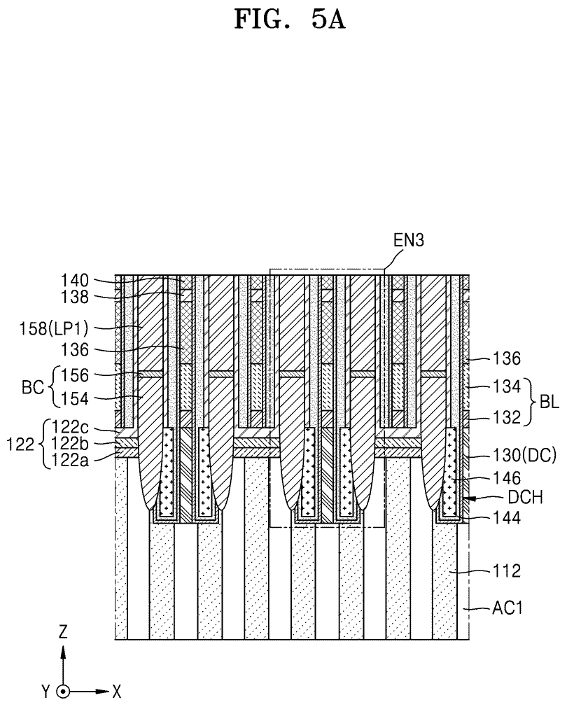

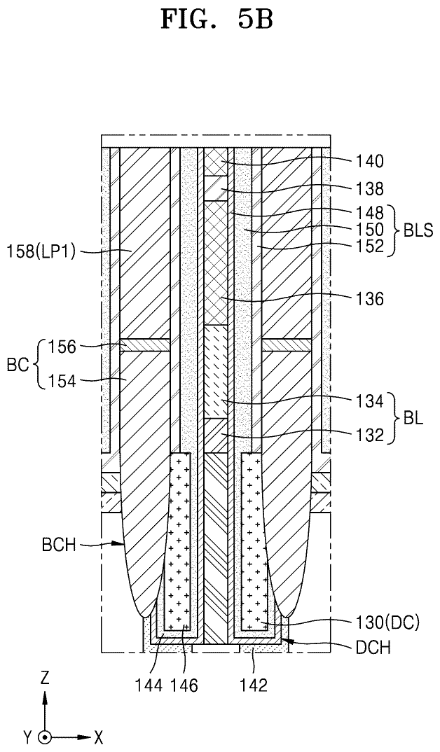

FIGS. 5A, 5B, 6 to 15 are views for explaining a method of manufacturing the semiconductor device EX1 of FIGS. 3A and 4A.

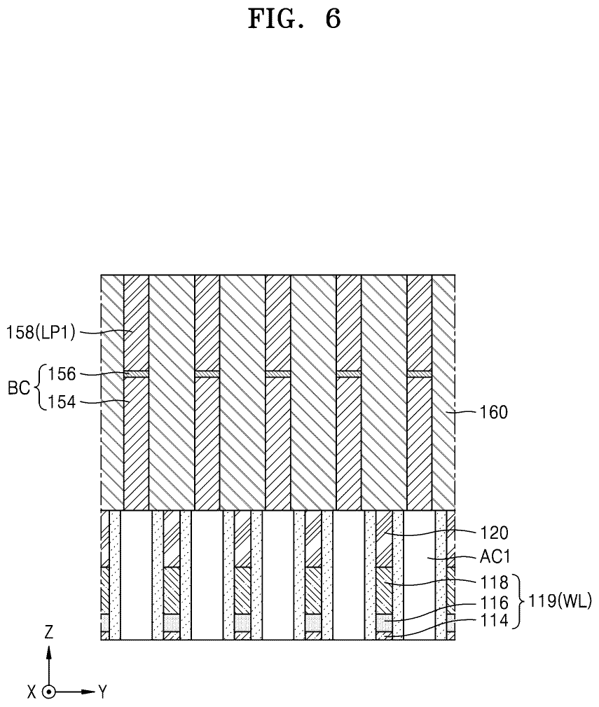

Specifically, FIGS. 5A, 5B, 8, 10, and 13 are cross-sectional views for explaining the method of manufacturing the semiconductor device EX1 of FIG. 2, taken in the first horizontal direction (X direction), that is, taken along line A1-A1′. FIGS. 6, 9, 11, and 14 are cross-sectional views for explaining the method of manufacturing the semiconductor device EX1 of FIG. 2, taken in the second horizontal direction (Y direction), that is, taken along line A2-A2′.

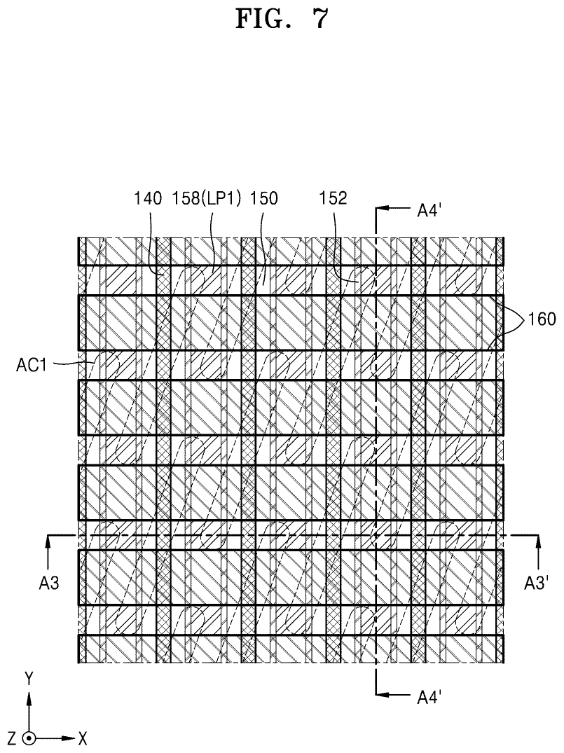

FIGS. 7, 12, and 15 may be plan views for explaining the method of manufacturing the semiconductor device EX1, according to a first horizontal direction (X direction) and a second horizontal direction (Y direction). The descriptions given with reference to FIGS. 3A to 4B are briefly given or omitted when describing FIGS. 5A to 15.

Referring to FIGS. 5A, 5B, 6, and 7, FIG. 5B is an enlarged view of region EN3 of FIG. 5A. FIG. 7 may be a plan view of FIGS. 5A and 5B along the first horizontal direction (X direction) and the second horizontal direction (Y direction). FIG. 5A may be a cross-sectional view of FIG. 7 taken in the first horizontal direction (X direction), that is, taken along line A3-A3′. FIG. 6 may be a cross-sectional view of FIG. 7 taken in the second horizontal direction (Y direction), that is, taken along line A4-A4′.

As shown in FIGS. 5A and 5B, a device isolation layer 112 defining a plurality of active regions AC1 is formed inside the semiconductor substrate 110 (FIG. 3A). A buffer layer 122 is formed on an active region AC1 and the device isolation layer 112.

A lower conductive pattern 130, a middle conductive pattern 132, an upper conductive pattern 134, a first insulating capping pattern 136, a second insulating capping pattern 138, and a third insulating capping pattern 140 are formed on the plurality of active regions AC1. In some embodiments, each of the second insulating capping pattern 138 and the third insulating capping pattern 140 may include a silicon nitride layer.

The spacer structures BLS may be formed on opposite sidewalls of the middle conductive pattern 132, the upper conductive pattern 134, the first insulating capping pattern 136, the second insulating capping pattern 138, and the third insulating capping pattern 140. Each of the spacer structures BLS may include a second inner spacer 148, a middle spacer 150, and an outer spacer 152. The middle conductive pattern 132 and the upper conductive pattern 134 may constitute a bit line BL.

The lower conductive pattern 130 may constitute a direct contact DC. When the lower conductive pattern 130 is formed, the device isolation layer 112 and the active region AC1 around the lower conductive pattern 130 may be etched to form a direct contact hole DCH. A first inner spacer 144 and a gap-fill insulating pattern 146 may be formed on the bottom of the direct contact hole DCH and the sidewall of the lower conductive pattern 130. The first inner spacer 144 and the second inner spacer 148 may be formed in the same process.

A plug conductive layer 154, a plug metal silicide layer 156, and a lower conductive pattern 158 are formed inside the semiconductor substrate 110 (FIG. 3A) between the lower conductive pattern 130, the middle conductive pattern 132, and the upper conductive pattern 134, the first insulating capping pattern 136, the second insulating capping pattern 138, and the third insulating capping pattern 140 in the first horizontal direction (X direction).

The plug conductive layer 154 passes through the buffer layer 122 and is formed in a buried contact hole BCH adjacent to the direct contact hole DCH. The buried contact hole BCH may be formed on the active region AC1 inside the semiconductor substrate 110 (FIG. 3A). The plug conductive layer 154 and a plug metal silicide layer 156 may form a buried contact plug BC. The lower conductive pattern 158 may constitute a first landing pad LP1.

As shown in FIG. 6, a plurality of word lines WL may be formed inside the device isolation layer 112. Each of the word lines WL may include gate conductive layers 114, 116, and 118. A gate cap layer 120 may be formed on the upper gate conductive layer 118.

A plurality of buried contact plugs BC and lower conductive patterns 158 are formed on the plurality of active regions AC1. A plurality of fence insulating material layers 160 are formed between the plurality of buried contact plugs BC and lower conductive patterns 158 above the gate cap layer 120 and the device isolation layer 112. Each of the fence insulating material layers 160 may include a silicon nitride layer.

Referring to FIG. 7, a plurality of third insulating capping patterns 140 may extend in the second horizontal direction (Y direction). The third insulating capping patterns 140 may be spaced apart from each other in the first horizontal direction (X direction). The middle spacer 150 and the outer spacer 152 may be located on one sidewall of the third insulating capping pattern 140. In FIG. 7, an inner spacer is not shown for convenience of description.

A plurality of lower conductive patterns 158 may extend in the second horizontal direction (Y direction). The lower conductive patterns 158 may be spaced apart from each other in the first horizontal direction (X direction). The lower conductive pattern 158 may constitute a first landing pad LP1. A plurality of fence insulating material layers 160 may extend in the first horizontal direction (X direction). The fence insulating material layers 160 may be spaced apart from each other in the second horizontal direction (Y direction).

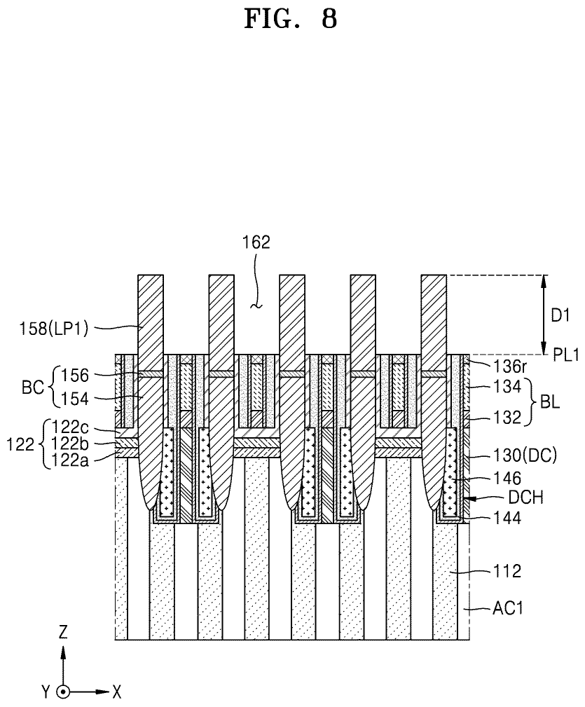

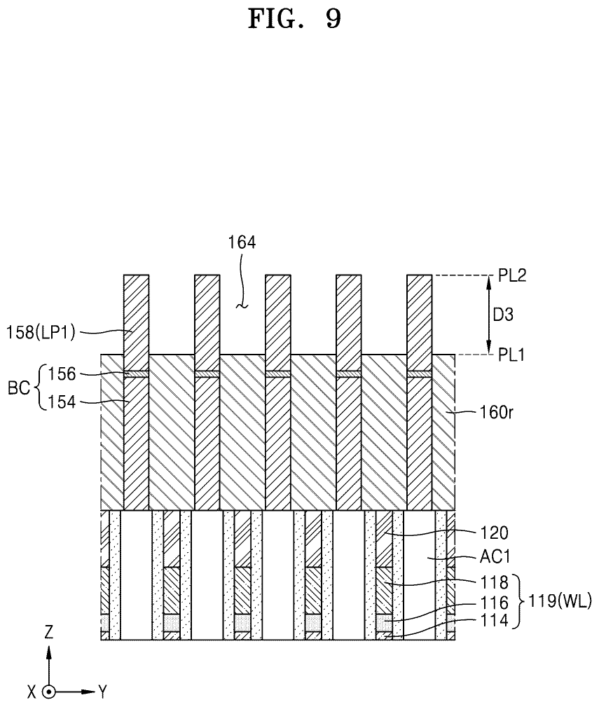

Referring to FIGS. 8 and 9, the third insulating capping pattern 140 (FIG. 5A), the second insulating capping pattern 138 (FIG. 5A), a portion of the first insulating capping pattern 136 (FIG. 5A), and a portion of the spacer structure BLS (FIG. 5B) are etched back as shown in FIG. 8.

In this case, the plurality of lower conductive patterns 158 may be spaced apart from each other in the first horizontal direction (X direction) and may be exposed to the outside. The first insulating capping pattern 136 (FIG. 5A) may be partially etched back to form an insulating capping patterns 136r with a reduced height. First recess opening holes 162, through which the insulating capping pattern 136r is exposed, may be formed between the plurality of lower conductive patterns 158. The lower conductive pattern 158 protrude, by a first vertical distance D1, from a first horizontal line PL1 on the upper surface of the insulating capping pattern 136r. In an embodiment, the lower conductive pattern 158 may vertically protrude beyond the upper surface of the insulating capping pattern 136r.

As shown in FIG. 9, the fence insulating material layer 160 (FIG. 6) is partially etched back. In this case, the plurality of lower conductive patterns 158 may be spaced apart from each other in the second horizontal direction (Y direction) and may be exposed to the outside. The fence insulating material layer 160 (FIG. 6) may be partially etched back to form a fence insulating layers 160r with a reduced height. Second recess opening holes 164, through which the fence insulating layer 160r is exposed, may be formed between the plurality of lower conductive patterns 158. The lower conductive pattern 158 protrude, by a third vertical distance D3, from the first horizontal line PL1 on the upper surface of the fence insulating layer 160r. In an embodiment, the lower conductive pattern 158 may protrude beyond the upper surface of the fence insulating layer 160r. The first horizontal line PL1 on the upper surface of the fence insulating material layer 160 may be positioned at the same height as the first horizontal line PL1 on the upper surface of the insulating capping pattern 136r.

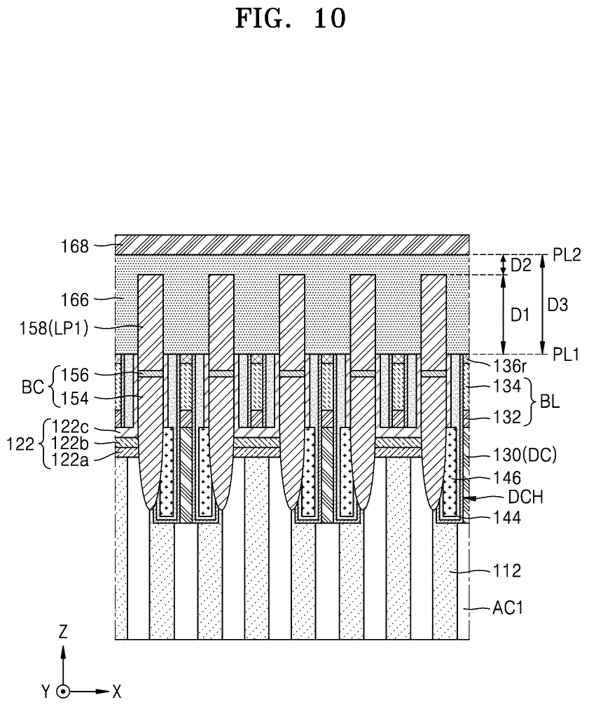

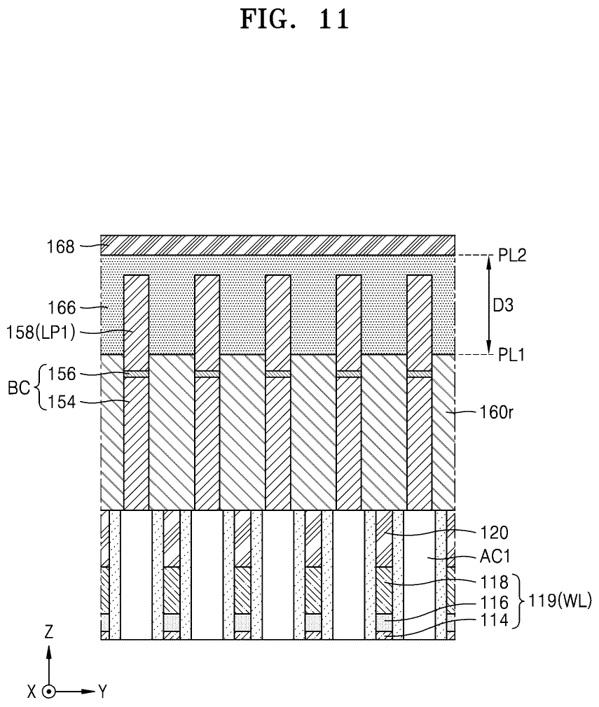

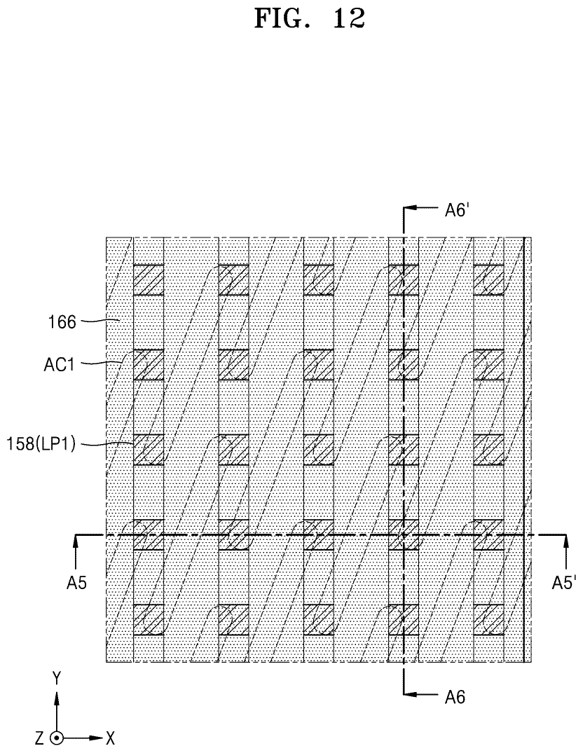

Referring to FIGS. 10, 11, and 12, FIG. 12 may be a plan view of FIGS. 10 and 11 according to the first horizontal direction (X direction) and the second horizontal direction (Y direction). FIG. 10 may be a cross-sectional view of FIG. 12 taken in the first horizontal direction (X direction), that is, taken along line A5-A5′. FIG. 11 may be a cross-sectional view of FIG. 12 taken in the second horizontal direction (Y direction), that is, taken along line A6-A6′.

As shown in FIG. 10, a landing insulating layer 166 is formed on the lower conductive pattern 158 while filling the first recess opening holes 162 (FIG. 8) between the plurality of lower conductive patterns 158 spaced apart from each other in the first horizontal direction (X direction). The landing insulating layer 166 may be formed on the lower conductive patterns 158 up to the level of the third vertical distance D3.

A stopper insulating layer 168 is formed on the landing insulating layer 166. The upper surface of the landing insulating layer 166 and the lower surface of the stopper insulating layer 168 may form a second horizontal line PL2. The vertical distance between the lower conductive pattern 158 and the second horizontal line PL2 may be equal to a second vertical distance D2.

As shown in FIG. 11, a landing insulating layer 166 is formed on the lower conductive pattern 158 while filling the second recess opening holes 164 (FIG. 9) between the plurality of lower conductive patterns 158 spaced apart from each other in the second horizontal direction (Y direction). The landing insulating layer 166 may be formed on the lower conductive patterns 158 up to the level of the third vertical distance D3. A stopper insulating layer 168 is formed on the landing insulating layer 166. The upper surface of the landing insulating layer 166 and the lower surface of the stopper insulating layer 168 may form a second horizontal line PL2.

As shown in FIG. 12, the plurality of lower conductive patterns 158 may be formed as island patterns, which are separated from each other in the first horizontal direction (X direction) and the second horizontal direction (Y direction).

As described above, the lower conductive patterns 158 may constitute the first landing pads LP1. The plurality of lower conductive patterns 158, that is, the first landing pads LP1, may be surrounded by the landing insulating layer 166. In FIG. 12, the stopper insulating layer 168 is not shown for convenience of description.

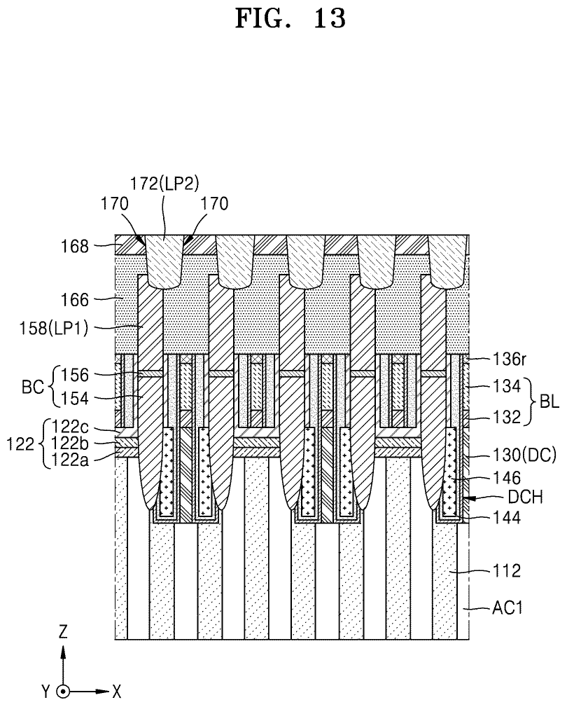

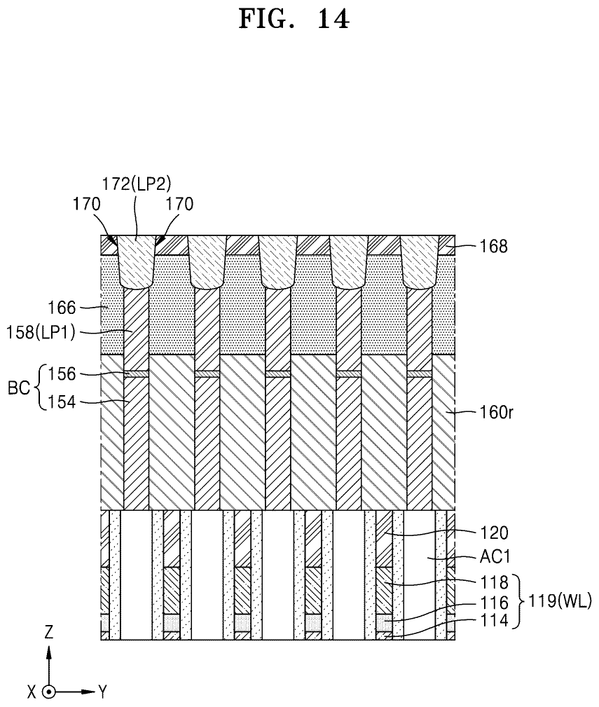

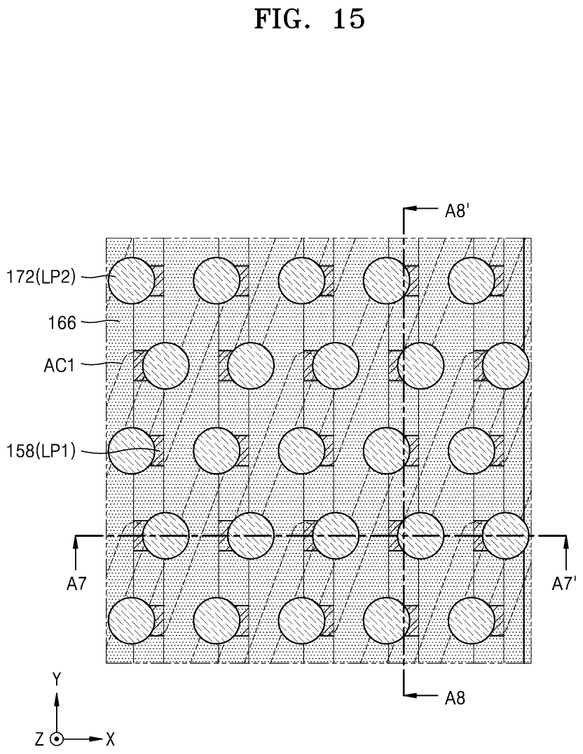

Referring to FIGS. 13, 14, and 15, FIG. 15 may be a plan view of FIGS. 13 and 14 according to the first horizontal direction (X direction) and the second horizontal direction (Y direction). FIG. 13 may be a cross-sectional view of FIG. 15 taken in the first horizontal direction (X direction), that is, taken along line A7-A7′. FIG. 14 may be a cross-sectional view of FIG. 15 taken in the second horizontal direction (Y direction), that is, taken along line A8-A8′.

As shown in FIG. 13, a plurality of landing opening holes 170 spaced apart from each other in the first horizontal direction (X direction) are formed in the stopper insulating layer 168 and the landing insulating layer 166. The landing opening holes 170 may be formed by patterning the landing insulating layer 166 and the stopper insulating layer 168 using a photoetching process. A conductive material layer may be buried in the landing opening holes 170 and then etched back to form upper conductive patterns 172, which are spaced apart from each other in the first horizontal direction (X direction).

The upper conductive patterns 172 may constitute second landing pads LP2. The second landing pads LP2 may be horizontally moved from the first landing pads LP1 in the first horizontal direction (X direction). A portion of the second landing pad LP2 may not vertically overlap the first landing pad LP1.

Referring to FIG. 14, a plurality of landing opening holes 170 spaced apart from each other in the second horizontal direction (Y direction) are formed in the stopper insulating layer 168 and the landing insulating layer 166 as shown in FIG. 14. The landing opening holes 170 may be formed by patterning the landing insulating layer 166 and the stopper insulating layer 168 using a photoetching process. A conductive material layer may be buried in the landing opening holes 170 and then etched back to form a plurality of upper conductive patterns 172, which are spaced apart from each other in the second horizontal direction (Y direction).

The upper conductive patterns 172 may constitute second landing pads LP2. The second landing pads LP2 may be not horizontally moved from the first landing pads LP1 in the second horizontal direction (Y direction). The second landing pad LP2 may vertically overlap the first landing pad LP1.

As shown in FIG. 15, the plurality of second landing pads LP2 may be formed as island patterns, which are separated from each other in the first horizontal direction (X direction) and the second horizontal direction (Y direction).

As described above, the upper conductive patterns 172 may constitute the second landing pads LP2. The plurality of upper conductive patterns 172, that is, the second landing pads LP2, may be surrounded by the landing insulating layer 166. In FIG. 15, the stopper insulating layer 168 is not shown for convenience of description.

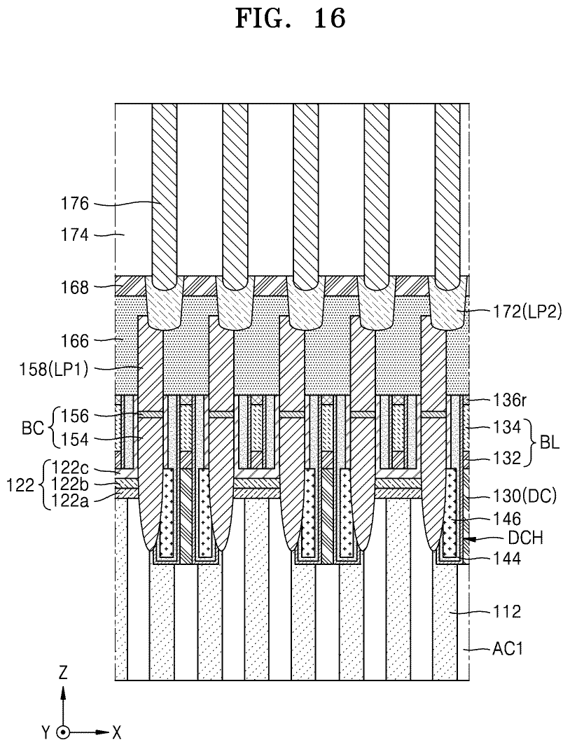

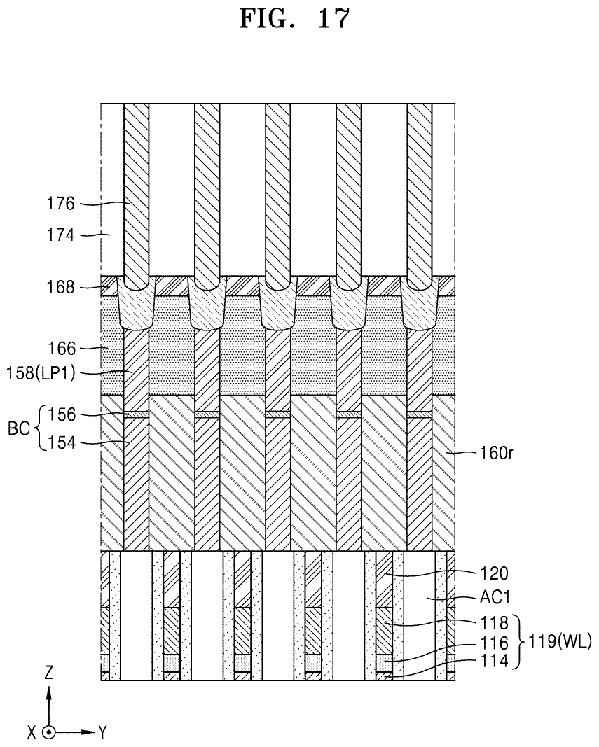

FIGS. 16 and 17 are cross-sectional views illustrating a semiconductor device including a storage electrode 176, according to an embodiment.

Specifically, FIG. 16 is a cross-sectional view of the semiconductor device EX1 of FIG. 2 taken in the first horizontal direction (X direction), that is, taken along line A1-A1′ and FIG. 17 is a cross-sectional view of the semiconductor device EX1 of FIG. 2 taken in the second horizontal direction (Y direction), that is, taken along line A2-A2′. The descriptions given with reference to FIGS. 3A, 3B, 4A, and 4B are briefly given or omitted when describing FIG. 16.

As shown in FIG. 16, storage electrodes 176 of capacitors may be respectively formed on the second landing pads LP2 spaced apart from each other in the first horizontal direction (X direction). Each of the storage electrodes 176 may include a lower electrode of a corresponding capacitor. After forming via holes in a mold insulating layer 174 on the stopper insulating layer 168, the storage electrodes 176 may be formed by filling the via holes with a conductive layer. The lower surface of the storage electrode 176 may have a concavely curved shape.

As shown in FIG. 17, the storage electrodes 176 may be respectively formed on the second landing pads LP2 spaced apart from each other in the second horizontal direction (Y direction). Each of the storage electrodes 176 may include the lower electrode of the corresponding capacitor. After forming via holes in a mold insulating layer 174 on the stopper insulating layer 168, the storage electrodes 176 may be formed by filling the via holes with a conductive layer. The lower surface of the storage electrode 176 may have a concavely curved shape.

As described above, the storage electrodes 176 may be formed on the second landing pads LP2 which are spaced apart from each other in the first horizontal direction (X direction) and the second horizontal direction (Y direction). The second landing pads LP2 may be spaced apart from each other in the first horizontal direction (X direction) and the second horizontal direction (Y direction).

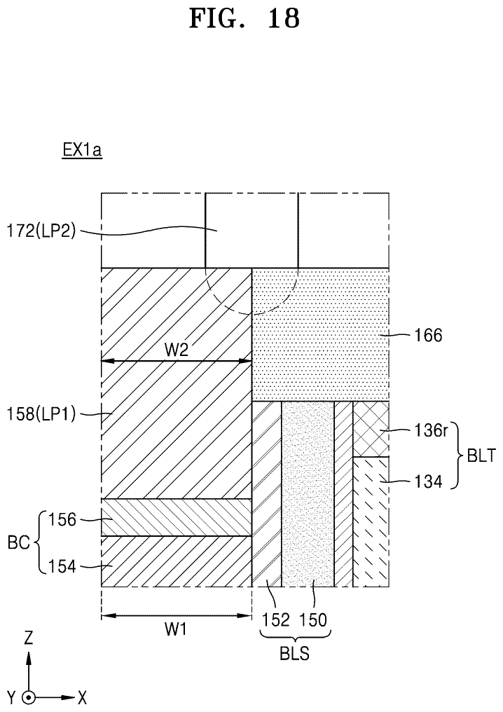

FIGS. 18 to 24 are cross-sectional views illustrating semiconductor devices EX1a, EX2, EX3, EX4, EX5, EX6, and EX7 including first landing pads LP1 and second landing pads LP2, according to an embodiment.

Specifically, FIGS. 18 to 24 may be cross-sectional views illustrating the vertical connection structures of the first landing pads LP1 and the second landing pads LP2. The descriptions given with reference to FIGS. 3A, 3B, 4A, and 4B are briefly given or omitted when describing FIGS. 18 to 24.

Referring to FIG. 18, the semiconductor device EX1a may include a bit line structure BLT, a buried contact plug BC, a first landing pad LP1, a landing insulating layer 166, and a second landing pad LP2. The bit line structure BLT may include an upper conductive pattern 134 and an insulating capping pattern 136r. The upper conductive pattern 134 may be included in the bit line BL (FIG. 3A).

A spacer structure BLS may be formed on one side of the bit line structure BLT. The spacer structure BLS may include a middle spacer 150 and an outer spacer 152. The buried contact plug BC and the first landing pad LP1 may be sequentially disposed on one side of the spacer structure BLS. The buried contact plug BC may include a plug conductive layer 154 and a plug metal silicide layer 156. The first landing pad LP1 may include a lower conductive pattern 158.

The buried contact plug BC may have a first width W1 in a first horizontal direction (X direction). The first landing pad LP1 may have a second width W2 in the first horizontal direction (X direction), which is equal to the first width W1. In an embodiment, an upper surface of the buried contact plug BC may have the first width W1, and a lower surface of the first landing pad LP1 may have the second width W2, which is equal to the first width W1.

The landing insulating layer 166 may be formed above the bit line structure BLT and on one side of the buried contact plug BC and the first landing pad LP1. The second landing pad LP2 may include an upper conductive pattern 172. The second landing pad LP2 may be connected to the first landing pad LP1 through an upper portion of the first landing pad LP1 and an upper portion of the landing insulating layer 166.

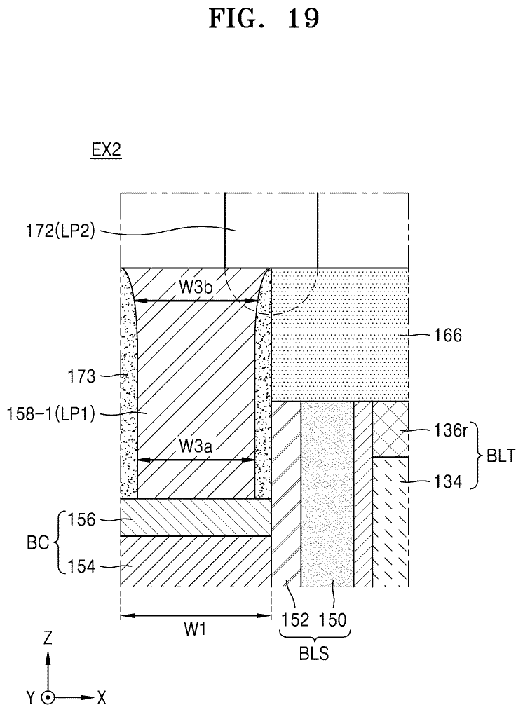

Referring to FIG. 19, the semiconductor device EX2 may be substantially the same as the semiconductor device EX1a of FIG. 18 except that the width of a lower conductive pattern 158-1 constituting a first landing pad LP1 is different from that of FIG. 18. The descriptions given with reference to FIG. 18 are briefly given or omitted when describing FIG. 19.

The first landing pad LP1 may include the lower conductive pattern 158-1. A buried contact plug BC may have a first width W1 in a first horizontal direction (X direction). The width of the lower conductive pattern 158-1 in the first horizontal direction (X direction) may be less than the first width W1. In other words, the width of the first landing pad LP1 may be less than the first width W1 of the buried contact plug BC.

The lower width and the upper width of the lower conductive pattern 158-1 in the first horizontal direction (X direction) may have a third width W3a and a fourth width W3b, respectively. The fourth width W3b may be greater than the third width W3a. A landing spacer 173 may be formed on one sidewall of the lower conductive pattern 158-1 of the first landing pad LP1. The landing spacer 173 may include a silicon nitride layer. In an embodiment, an upper surface of the buried contact plug BC may have the first width W1, and a lower surface of the lower conductive pattern 158-1 may have the third width W3a less than the first width W1. In an embodiment, a lower surface of the combined structure of the lower conductive pattern 158-1 and the landing spacer 173 may have a width equal to the first width W1 of the upper surface of the buried contact plug BC. In an embodiment, the lower conductive pattern 158-1 may have a lower portion having a constant width of the third width W3a and an upper portion having an increasing width from the third width W3a to the first width W1.

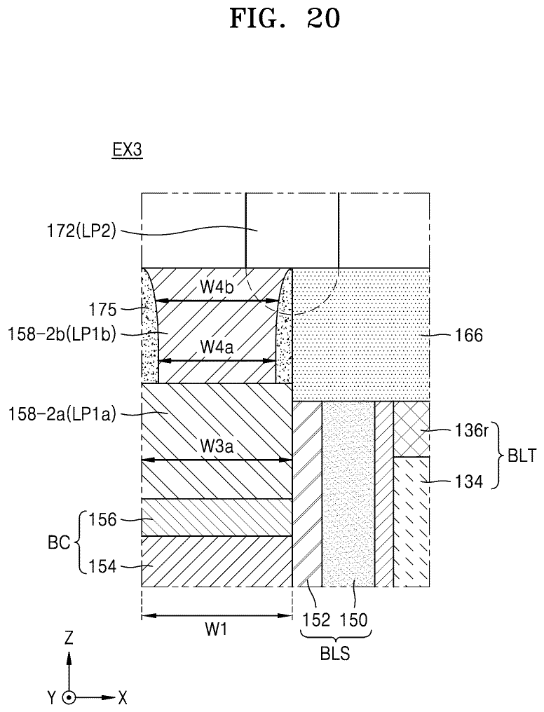

Referring to FIG. 20, the semiconductor device EX3 may be the same as the semiconductor device EX1a of FIG. 18, except that the first landing pad LP1 (FIG. 18) includes a first sub-landing pad LP1a and a second sub-landing pad LP1b and the width of the second sub-landing pad LP1b is different from the width of the first sub-landing pad LP1a. The descriptions given with reference to FIG. 18 are briefly given or omitted when describing FIG. 20.

The first landing pad LP1 (FIG. 18) may include the first sub-landing pad LP1a and the second sub-landing pad LP1b. The first sub-landing pad LP1a may include a first lower electrode pattern 158-2a. The first sub-landing pad LP1a may have a third width W3a in the first horizontal direction (X direction). The second sub-landing pad LP1b may include a second lower electrode pattern 158-2b.

The lower width and the upper width of the second lower electrode pattern 158-2b in the first horizontal direction (X direction) may have a fifth width W4a and a sixth width W4b, respectively. The sixth width W4b may be greater than the fifth width W4a. A landing spacer 175 may be formed on one sidewall of the second lower electrode pattern 158-2b. The landing spacer 175 may include a silicon nitride layer. In an embodiment, a lower surface of the combined structure of the second lower electrode pattern 158-2b and the landing spacer 175 may have a width equal to a width of an upper surface of the first sub-landing pad LP1a. The width of the upper surface of the first sub-landing pad LP1a may have a constant width of the third width W3a. In an embodiment, the second lower electrode pattern 158-2b may have a lower portion having a constant width of the fifth width W4a and an upper portion having an increasing width from the fifth width W4a to the third width W3a.

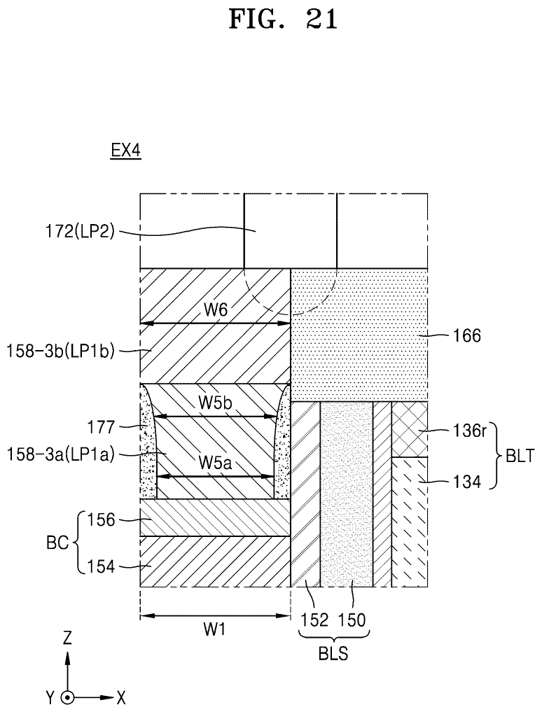

Referring to FIG. 21, the semiconductor device EX4 may be substantially the same as the semiconductor device EX1a of FIG. 18, except that the first landing pad LP1 (FIG. 18) includes a first sub-landing pad LP1a and a second sub-landing pad LP1b and the width of the first sub-landing pad LP1a is different from the width of the second sub-landing pad LP1b. The descriptions given with reference to FIG. 18 are briefly given or omitted when describing FIG. 21.

The first landing pad LP1 (FIG. 18) may include the first sub-landing pad LP1a and the second sub-landing pad LP1b. The first sub-landing pad LP1a may include a first lower electrode pattern 158-3a.

The lower width and the upper width of the first lower electrode pattern 158-3a in the first horizontal direction (X direction) may have a seventh width W5a and an eighth width W5b, respectively. The eighth width W5b may be greater than the seventh width W5a. A landing spacer 177 may be formed on one sidewall of the first lower electrode pattern 158-3a. The landing spacer 177 may include a silicon nitride layer.

The second sub-landing pad LP1b may include a second lower electrode pattern 158-3b. The width of the second lower electrode pattern 158-3b in the first horizontal direction (X direction) may have a ninth width W6. The ninth width W6 may be equal to the first width W1. In an embodiment, an upper surface of the first lower electrode pattern 158-3a may have a width equal to a width (e.g., the ninth width W6) of a lower surface of the second sub-landing pad LP1b. The combined structure of the first sub-landing pad LP1a and the landing spacer 177 may have a constant width which is equal to the ninth width W6 of the lower surface of the second sub-landing pad LP1b or which is equal to the first width W1 of an upper surface of the buried contact plug BC. In an embodiment, the first sub-landing pad LP1a may have a lower portion having a constant width of the seventh width W5a and an upper portion having an increasing width from the seventh width W5a to the ninth width W6.

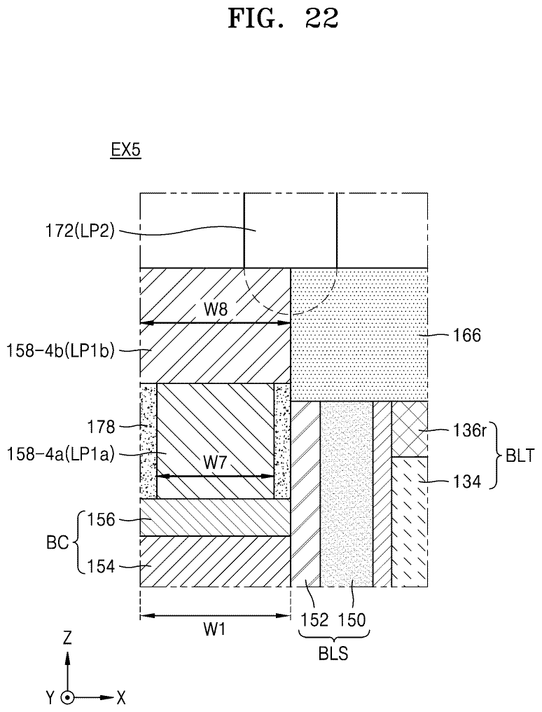

Referring to FIG. 22, the semiconductor device EX5 may be substantially the same as the semiconductor device EX1a of FIG. 18, except that the first landing pad LP1 (FIG. 18) includes a first sub-landing pad LP1a and a second sub-landing pad LP1b and the width of the first sub-landing pad LP1a is different from the width of the second sub-landing pad LP1b. The descriptions given with reference to FIG. 18 are briefly given or omitted when describing FIG. 22.

The first landing pad LP1 (FIG. 18) may include the first sub-landing pad LP1a and the second sub-landing pad LP1b. The first sub-landing pad LP1a may include a first lower electrode pattern 158-4a.

The width of the first lower electrode pattern 158-4a in the first horizontal direction (X direction) may have a tenth width W7. The tenth width W7 may be less than the first width W1. A landing spacer 178 may be formed on one sidewall of the first lower electrode pattern 158-4a. The landing spacer 178 may include a silicon nitride layer.

The second sub-landing pad LP1b may include a second lower electrode pattern 158-4b. The width of the second lower electrode pattern 158-4b in the first horizontal direction (X direction) may have an eleventh width W8. The eleventh width W8 may be equal to the first width W1. In an embodiment, the second sub-landing pad LP1b may have a constant width of the eleventh width W8, and the first sub-landing pad LP1a may have a constant width of the tenth W7. In an embodiment, the combined structure of the first sub-landing pad LP1a and the landing spacer 178 may have a constant width of the eleventh width W8 or a constant width of the first width W1.

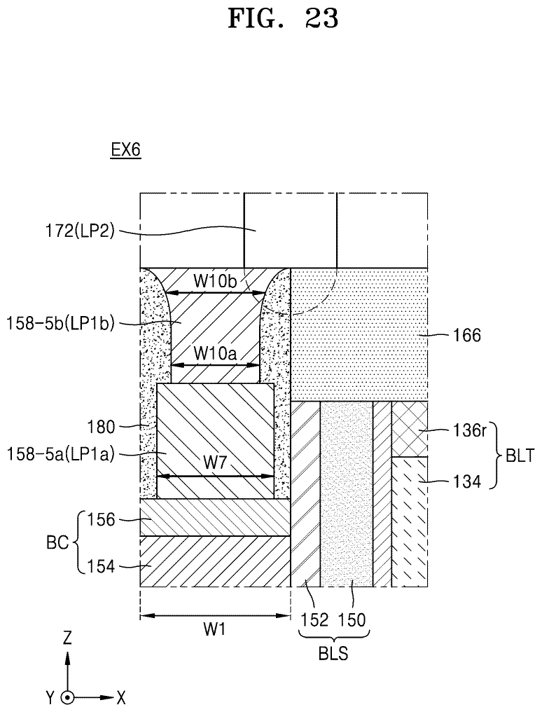

Referring to FIG. 23, the semiconductor device EX6 may be substantially the same as the semiconductor device EX1a of FIG. 18, except that the first landing pad LP1 (FIG. 18) includes a first sub-landing pad LP1a and a second sub-landing pad LP1b and the width of the first sub-landing pad LP1a is different from the width of the second sub-landing pad LP1b. The descriptions given with reference to FIG. 18 are briefly given or omitted when describing FIG. 23.

The first landing pad LP1 (FIG. 18) may include the first sub-landing pad LP1a and the second sub-landing pad LP1b. The first sub-landing pad LP1a may include a first lower electrode pattern 158-5a. The width of the first lower electrode pattern 158-5a in the first horizontal direction (X direction) may have a tenth width W7. The tenth width W7 may be less than the first width W1.

The second sub-landing pad LP1b may include a second lower electrode pattern 158-5b. The lower width and the upper width of the second lower electrode pattern 158-5b in the first horizontal direction (X direction) may have a twelfth width W10a and an thirteenth width W10b, respectively. The thirteenth width W10b may be greater than the twelfth width W10a.

A landing spacer 180 may be formed on one sidewall of the first lower electrode pattern 158-5a and the second lower electrode pattern 158-5b. The landing spacer 180 may include a silicon nitride layer. In an embodiment, the buried contact BC may have an upper surface having the first width W1, the first sub-landing pad LP1a may have a constant width of the tenth width W7, and the second sub-landing pad LP1b may have a lower surface having the twelfth width W10a. In an embodiment, the second sub-landing pad LP1b may have a lower portion having a constant width of the twelfth width W10a and an upper portion having an increasing width from the twelfth W10a to the first width W1. In an embodiment, the combined structure of the landing spacer 180, the first sub-landing pad LP1a, and the second sub-landing pad LP1b may have a constant width of the first width W1. In an embodiment, the landing spacer 180 may contact the upper surface of the first sub-landing pad LP1a.

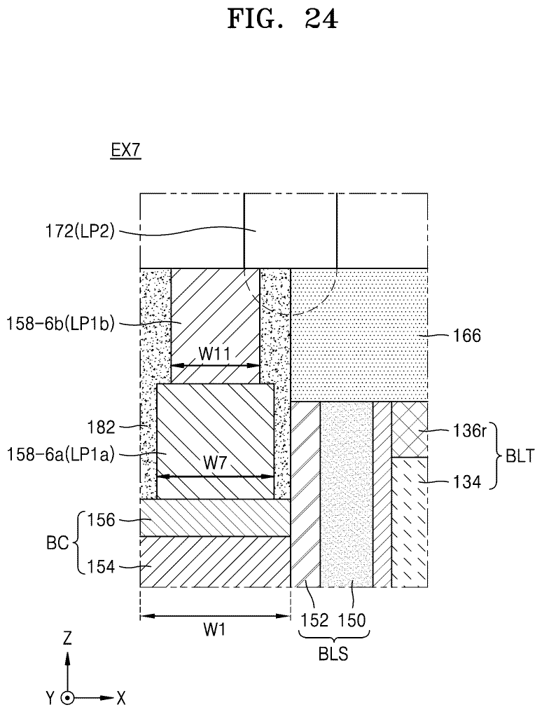

Referring to FIG. 24, the semiconductor device EX7 may be substantially the same as the semiconductor device EX1a of FIG. 18, except that the first landing pad LP1 (FIG. 18) includes a first sub-landing pad LP1a and a second sub-landing pad LP1b and the width of the first sub-landing pad LP1a is different from the width of the second sub-landing pad LP1b. The descriptions given with reference to FIG. 18 are briefly given or omitted when describing FIG. 24.

The first landing pad LP1 (FIG. 18) may include the first sub-landing pad LP1a and the second sub-landing pad LP1b. The first sub-landing pad LP1a may include a first lower electrode pattern 158-6a. The width of the first lower electrode pattern 158-6a in the first horizontal direction (X direction) may have a tenth width W7. The tenth width W7 may be less than the first width W1.

The second sub-landing pad LP1b may include a second lower electrode pattern 158-6b. The width of the second lower electrode pattern 158-6b in the first horizontal direction (X direction) may have a fourteenth width W11. The fourteenth width W11 may be less than the tenth width W7. A landing spacer 182 may be formed on one sidewall of the first lower electrode pattern 158-6a and the second lower electrode pattern 158-6b. The landing spacer 182 may include a silicon nitride layer. In an embodiment, the first sub-landing pad LP1a may have a constant width of the tenth width W7, and the second sub-landing pad LP1b may have a constant width of the fourteenth width W11. In an embodiment, the combined structure of the landing spacer 182, the first sub-landing pad LP1a, and the second sub-landing pad LP1b may have a constant width of the first width W1.

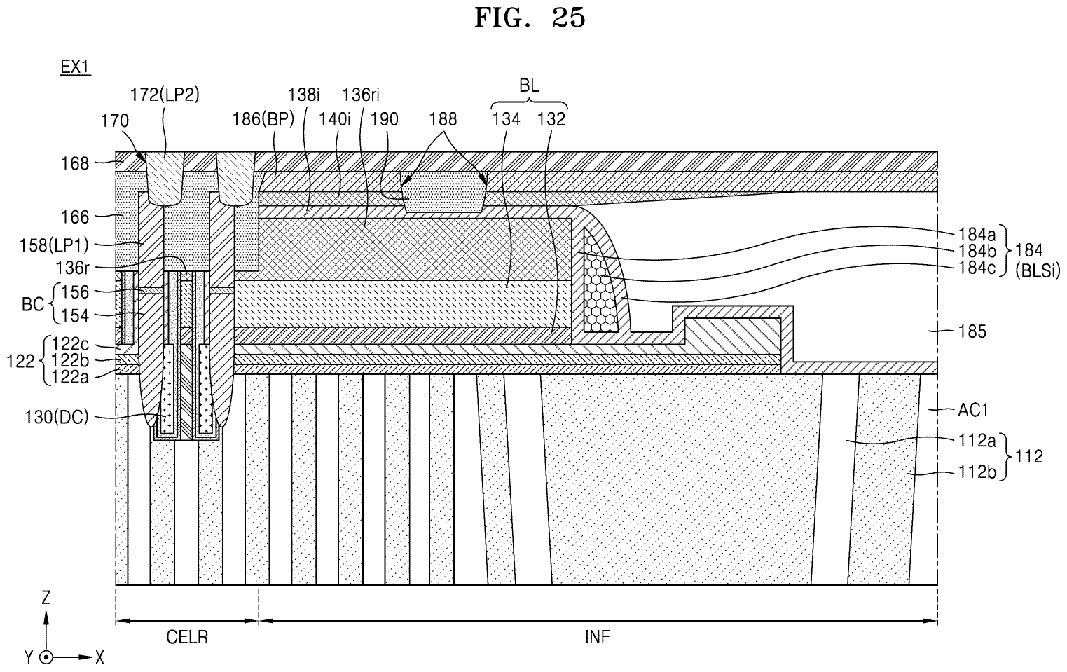

FIGS. 25 to 27 are cross-sectional views illustrating a semiconductor device EX1 including a cell region CELR, an interface region INF, and a core region COR, according to an embodiment.

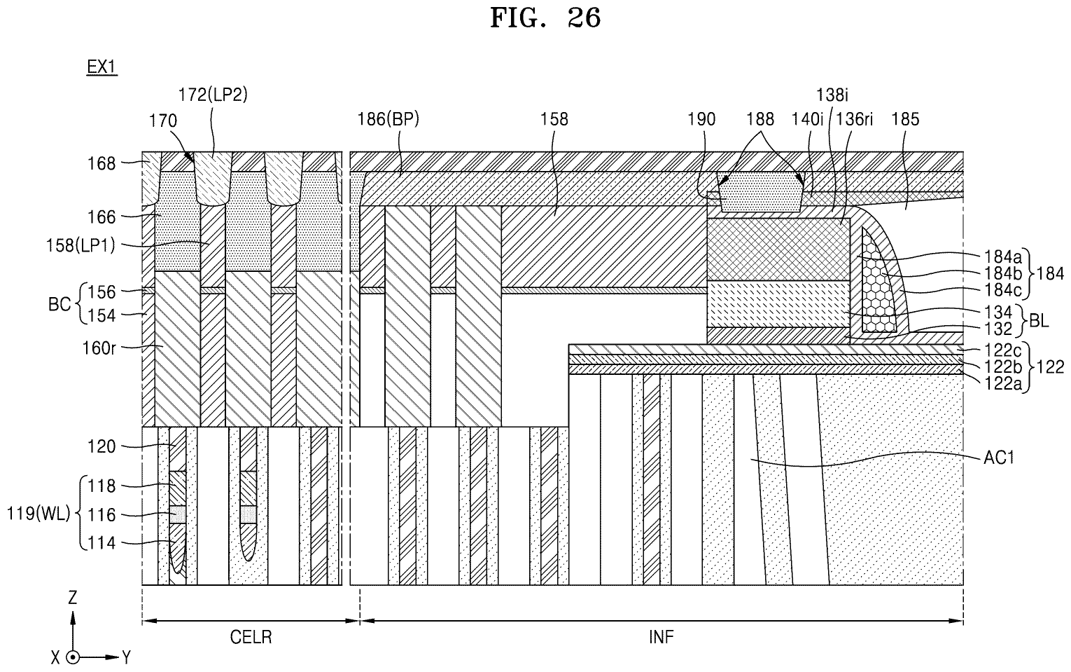

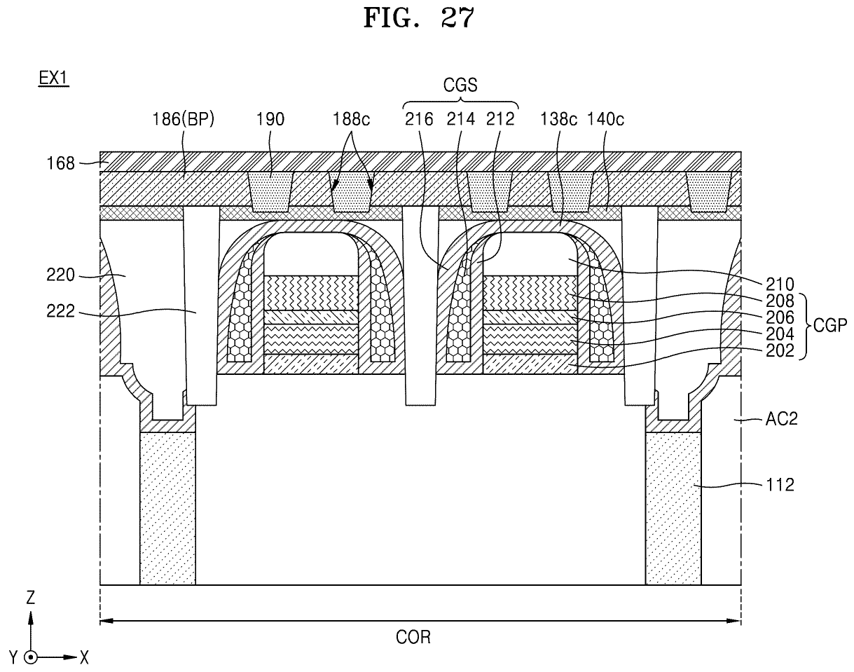

Specifically, FIGS. 25 and 26 are cross-sectional views showing the semiconductor device EX1 including the cell region CELR of FIGS. 3A and 4A, respectively, and the interface region INF adjacent to the cell region CELR according to an embodiment. FIG. 27 is a cross-sectional view showing the core region COR of the semiconductor device EX1 according to an embodiment. The descriptions given with reference to FIGS. 3A to 4B are briefly given or omitted when describing FIGS. 25 to 27.

Referring to FIG. 25, the semiconductor device EX1 may include device isolation layers 112 and active regions AC1 formed inside the semiconductor substrate 110 (FIG. 3A). Each of the device isolation layers 112 may include a silicon oxide film 112a and a silicon nitride film 112b.

A buffer layer 122 formed in the cell region CELR may also exist in the interface region INF. The buffer layer 122 may include a first silicon oxide film 122a, a second silicon oxide film 122b, and a silicon nitride film 122c. In an embodiment, the buffer layer 122 may continuously extend both in the cell region CELR and the interface region INF.

A plurality of bit lines BL are formed on the buffer layer 122 and spaced apart from each other in a first horizontal direction (X direction). The bit lines BL may also be formed in the interface region INF. Each of the bit lines BL may include a middle conductive pattern 132 and an upper conductive pattern 134. The spacer structure BLS (FIG. 5B) may be formed between the plurality of bit lines BL.

Direct contacts DC connected to the active regions AC1 may be formed below the bit lines BL in the cell region CELR. Buried contact plugs BC may be formed between the plurality of bit lines BL in the cell region CELR. Each of the buried contact plugs BC may include a plug conductive layer 154 and a plug metal silicide layer 156.

An insulating capping pattern 136r is formed on the bit lines BL in the cell region CELR. A first interface insulating capping pattern 136ri corresponding to the insulating capping pattern 136r may be formed in the interface region INF. The first interface insulating capping pattern 136ri of the interface region INF may be thicker than the insulating capping pattern 136r of the cell region CELR. In an embodiment, the first interface insulating capping pattern 136ri and the insulating capping pattern 136r may be formed from the same material layer.

A second interface insulating capping pattern 138i and a third interface insulating capping pattern 140i may be formed on the first interface insulating capping pattern 136ri. Each of the second interface insulating capping pattern 138i and the third interface insulating capping pattern 140i may include a silicon nitride layer.

An interface spacer structure 184 (BLSi) may be formed on one sidewall of the bit lines BL, the first interface insulating capping pattern 136ri, and the second interface insulating capping pattern 138i in the interface region INF. The interface spacer structure 184 may include a silicon nitride film 184a, a silicon oxide film 184b, and a silicon nitride film 184c. An interface interlayer insulating layer 185 may be formed in the interface region INF. The interface interlayer insulating layer 185 may include a silicon oxide layer.

A plurality of buried patterns BP may be formed on the third interface insulating capping pattern 140i and the interface interlayer insulating layer 185 in the interface region INF. Each of the buried patterns BP may include a conductive layer 186. The conductive layer 186 may include doped polysilicon, metal, metal silicide, conductive metal nitride, or a combination thereof. In some embodiments, the conductive layer 186 may include or may be formed of tungsten (W).

First landing pads LP1 may be formed on the buried contact plug BC of the cell region CELR and spaced apart from each other in the first horizontal direction (X direction). Each of the first landing pads LP1 protrudes from the surface of the insulating capping pattern 136r above the bit line BL. Each of the first landing pads LP1 may include a lower conductive pattern 158. The upper surface of the first landing pad LP1 may be substantially the same as the upper surface of the second interface insulating capping pattern 138i.

In the cell region CELR, a landing insulating layer 166 may surround the sidewalls of the first landing pads LP1 and cover the upper portions of the plurality of first landing pads LP1. An interface opening hole 188 is formed inside the conductive layer 186 of the interface region INF using a photo etching process including a photolithography process to define a region to be etched and then a etching process for removing the region. In some embodiments, the lower surface of the interface opening hole 188 may be located on the upper surface of the second interface insulating capping pattern 138i.

An interface insulating layer 190 is formed inside the interface opening hole 188. The interface insulating layer 190 includes a silicon oxide layer. The landing insulating layer 166 of the cell region CELR and the interface insulating layer 190 of the interface region INF may be formed during the same process.

A stopper insulating layer 168 is formed on the landing insulating layer 166 in the cell region CELR and the interface region INF. Landing opening holes 170 are formed in the landing insulating layer 166 and the stopper insulating layer 168 in the cell region CELR. Second landing pads LP2 connected to the first landing pads LP1 are formed in the landing opening holes 170. Each of the second landing pads LP2 may include an upper conductive pattern 172.

Referring to FIG. 26, the semiconductor device EX1 may include device isolation layers 112 and active regions AC1 formed inside the semiconductor substrate 110 (FIG. 3A). Each of the device isolation layers 112 may include a silicon oxide film 112a and a silicon nitride film 112b.

A plurality of word lines 119 (WL of FIG. 2) may be arranged inside the device isolation layers 112 of the cell region CELR. Each of the word lines 119 may include gate conductive layers 114, 116, and 118. A gate cap layer 120 may be formed on an upper gate conductive layer 118 among the gate conductive layers 114, 116, and 118. A plurality of buried contact plugs BC may be formed on the plurality of active regions AC1 in the cell region CELR. Each of the buried contact plugs BC may include a plug conductive layer 154 and a plug metal silicide layer 156. A plurality of fence insulating layers 160r are formed on the gate cap layers 120 and the device isolation layers 112.

A buffer layer 122 may be formed in the interface region INF. A buried contact plug BC may be formed on the buffer layer 122. The bit line BL, the first interface insulating capping pattern 136ri, the second interface insulating capping pattern 138i, the third interface insulating capping pattern 140i, the interface spacer structure 184 (BLSi), and the interface interlayer insulating layer 185, which have been described in FIG. 25, may be formed on the buffer layer 122 of the interface region INF.

A plurality of first landing pads LP1 may be formed on the buried contact plug BC in the cell region CELR. The fence insulating layer 160r may partially cover the lower portions of the first landing pads LP1. Each of the first landing pads LP1 may include a lower conductive pattern 158. A lower conductive pattern 158 may also be formed on the buried contact plug BC in the interface region INF.

A plurality of buried patterns BP may be formed on the third interface insulating capping pattern 140i and the interface interlayer insulating layer 185 in the interface region INF. Each of the buried patterns BP may include a conductive layer 186.

The first landing pads LP1 may be formed on the buried contact plug BC of the cell region CELR and spaced apart from each other in the second horizontal direction (Y direction). Each of the first landing pads LP1 protrudes from the surface of the fence insulating layer 160r. Each of the first landing pads LP1 may include a lower conductive pattern 158. The upper surface of the first landing pad LP1 may be substantially the same as the upper surface of the second interface insulating capping pattern 138i. The lower conductive patterns 158 that are formed in the interface region INF correspond to the first landing pads LP1 in the cell region CELR.

In the cell region CELR, a landing insulating layer 166 may have a configuration similar to FIG. 25. For example, the landing insulating layer 166 may surround the sidewalls of the first landing pads LP1 and cover the upper portions of the first landing pads LP1. An interface opening hole 188 is formed inside the conductive layer 186 of the interface region INF using a photo etching process. In some embodiments, the lower surface of the interface opening hole 188 may be located on the upper surface of the second interface insulating capping pattern 138i.

An interface insulating layer 190 is formed inside the interface opening hole 188. The interface insulating layer 190 includes a silicon oxide layer. The landing insulating layer 166 of the cell region CELR and the interface insulating layer 190 of the interface region INF may be formed during the same process.

A stopper insulating layer 168 is formed on the landing insulating layer 166 in the cell region CELR and the interface region INF. Landing opening holes 170 are formed in the landing insulating layer 166 and the stopper insulating layer 168 in the cell region CELR. Second landing pads LP2 connected to the first landing pads LP1 are formed in the landing opening holes 170. Each of the second landing pads LP2 may include an upper conductive pattern 172.

Referring to FIG. 27, the semiconductor device EX1 may include device isolation layers 112 and active regions AC2 formed inside the semiconductor substrate 110 (FIG. 3A) of the core region COR. A core gate dielectric layer 202, core gate conductive layers 204, 206, and 208, and a first core insulating capping pattern 210 may be formed on the active regions AC2. The core gate dielectric layer 202 and the core gate conductive layers 204, 206, and 208 may constitute a core gate pattern CGP.

The core gate dielectric layer 202 may include at least one selected from among a silicon oxide film, a silicon nitride film, a silicon oxynitride film, an oxide/nitride/oxide (ONO) film, and a high-k dielectric film having a higher dielectric constant than the silicon oxide film. Each of the core gate conductive layers 204, 206, and 208 may include Ti, TiN, Ta, TaN, W, WN, TiSiN, WSiN, or a combination thereof. The first core insulating capping pattern 210 may include a silicon nitride layer.

A core gate spacer CGS may be formed on one sidewall of the core gate pattern CGP. The core gate spacer CGS may include a first core gate spacer 212, a second core gate spacer 214, and a third core gate spacer 216.

The first core gate spacer 212, the second core gate spacer 214, and the third core gate spacer 216 may include a silicon nitride layer, a silicon oxide layer, and a silicon nitride layer. A second core insulating capping pattern 138c may be formed on the first core insulating capping pattern 210.

A core interlayer insulating layer 220 may be formed above the active region AC2, the core gate pattern CGP, the third core gate spacer 216, and the second core insulating capping pattern 138c. The core interlayer insulating layer 220 may include a silicon oxide layer. A third core insulating capping pattern 140c may be formed on the core interlayer insulating layer 220 and the second core insulating capping pattern 138c. The third core insulating capping pattern 140c may include a silicon nitride layer.

A contact plug 222 connected to the active region AC2 may be formed inside the core interlayer insulating layer 220 and the third core insulating capping pattern 140c. A plurality of core buried patterns BP may be formed on the contact plug 222 and the third core insulating capping pattern 140c. Each of the core buried patterns BP may include a conductive layer 186.

A core opening hole 188c is formed inside the conductive layer 186 of the core region COR using a photo etching process. In some embodiments, the lower surface of the core opening hole 188c may be located on the upper surface of the third core insulating capping pattern 140c.

A core insulating layer 190c is formed inside the core opening hole 188c. The core insulating layer 190c includes a silicon oxide layer. The landing insulating layer 166 of the cell region CELR, the interface insulating layer 190 of the interface region INF in FIGS. 25 and 26, and the core insulating layer 190c of the core region COR may be formed during the same process. A stopper insulating layer 168 may be formed on the core region COR.

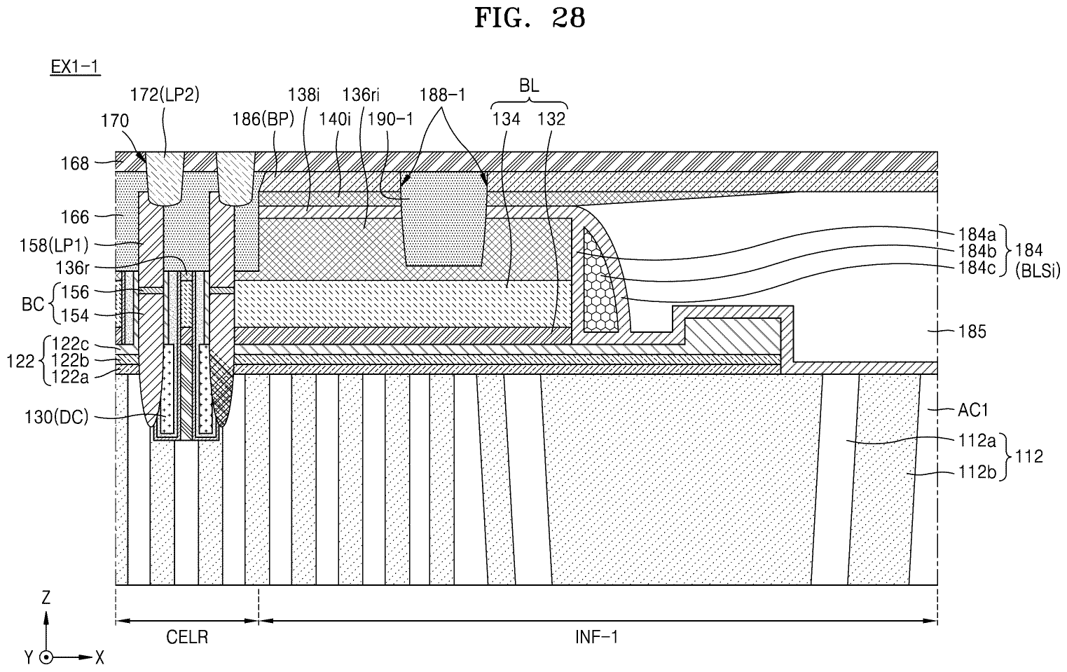

FIGS. 28 to 30 are cross-sectional views illustrating a semiconductor device EX1-1 including a cell region CELR, an interface region INF-1, and a core region COR-1, according to an embodiment.

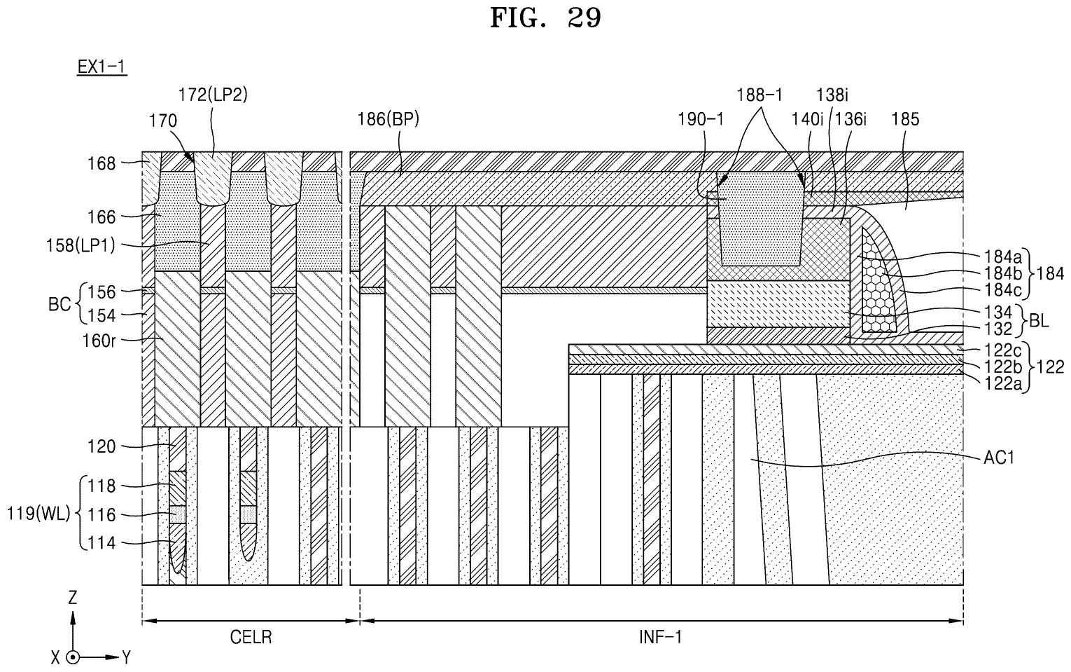

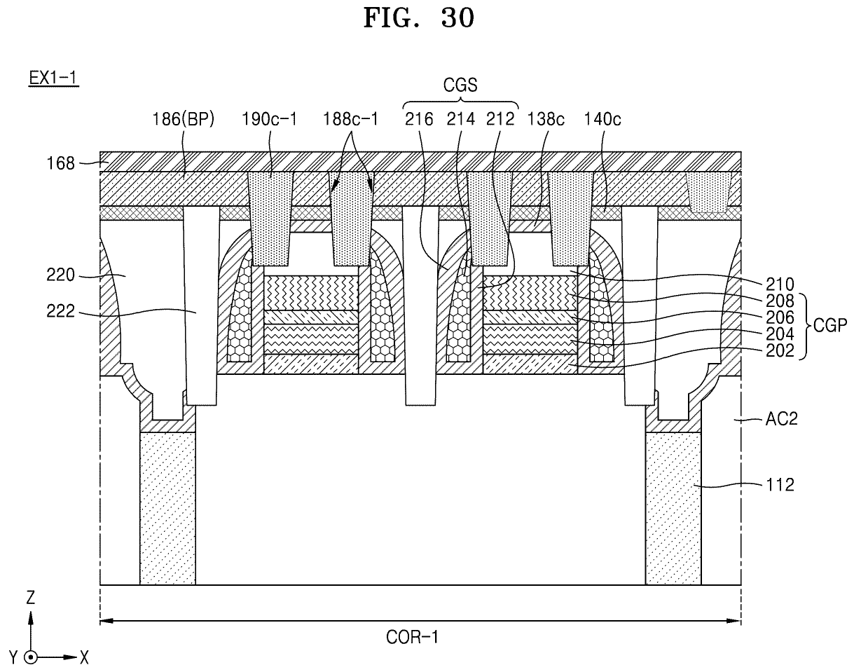

Specifically, FIGS. 28 and 29 are cross-sectional views showing the semiconductor device EX1-1 including the cell region CELR of FIGS. 3A and 4A, respectively, and the interface region INF-1 adjacent to the cell region CELR according to an embodiment. FIG. 30 is a cross-sectional view showing the core region COR-1 of the semiconductor device EX1-1 according to an embodiment.

The semiconductor device EX1-1 may be substantially the same as the semiconductor device EX1 of FIGS. 25 to 27, except that the structures of an interface opening hole 188-1 and a core opening hole 188c-1 of the semiconductor device EX1-1 are different from those of the semiconductor device EX1. The descriptions given with reference to FIGS. 25 to 27 are briefly given or omitted when describing FIGS. 28 to 30.

Referring to FIGS. 28 and 29, a landing insulating layer 166 may be formed in the cell region CELR, surround the sidewalls of a plurality of first landing pads LP1, and cover the upper portions of the plurality of first landing pads LP1.

In the interface region INF-1, an interface opening hole 188-1 may be formed, using a photo etching process, inside a conductive layer 186 constituting a buried pattern BP, a third interface insulating capping pattern 140i, a second interface insulating capping pattern 138i, and a first interface insulating capping pattern 136ri.

In some embodiments, the lower surface of the interface opening hole 188-1 may be located inside the first interface insulating capping pattern 136ri. The interface opening hole 188-1 may be deeper than the interface opening hole 188 of FIGS. 25 and 26. An interface insulating layer 190-1 is formed inside the interface opening hole 188-1. The interface insulating layer 190-1 includes a silicon oxide layer. The landing insulating layer 166 of the cell region CELR and the interface insulating layer 190-1 of the interface region INF-1 may be formed during the same process.

A stopper insulating layer 168 is formed on the landing insulating layer 166 in the cell region CELR and the interface region INF-1. Landing opening holes 170 are formed in the landing insulating layer 166 and the stopper insulating layer 168 in the cell region CELR. Second landing pads LP2 connected to the first landing pads LP1 are formed in the landing opening holes 170. Each of the second landing pads LP2 may include an upper conductive pattern 172.

Referring to FIG. 30, in the core region COR-1, a core opening hole 188c-1 may be formed, using a photo etching process, inside a conductive layer 186 constituting a core buried pattern BP, a third core insulating capping pattern 140c, a second core insulating capping pattern 138c, and a first core insulating capping pattern 210. In some embodiments, the lower surface of the core opening hole 188c-1 may be located inside the first core insulating capping pattern 210.

A core insulating layer 190c-1 is formed inside the core opening hole 188c-1. The core insulating layer 190c-1 includes a silicon oxide layer. The landing insulating layer 166 of the cell region CELR, the interface insulating layer 190-1 of the interface region INF-1 in FIGS. 28 and 29, and the core insulating layer 190c-1 of the core region COR-1 may be formed during the same process. A stopper insulating layer 168 may be formed on the core region COR-1.

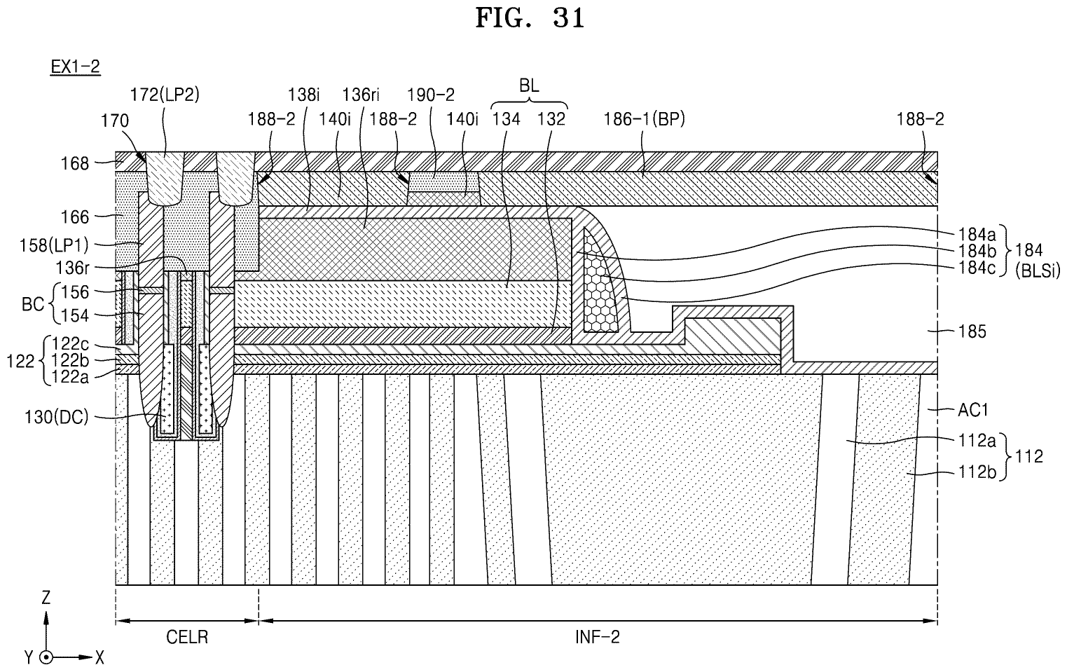

FIGS. 31 to 33 are cross-sectional views illustrating a semiconductor device EX1-2 including a cell region CELR, an interface region INF-2, and a core region COR-2, according to an embodiment.

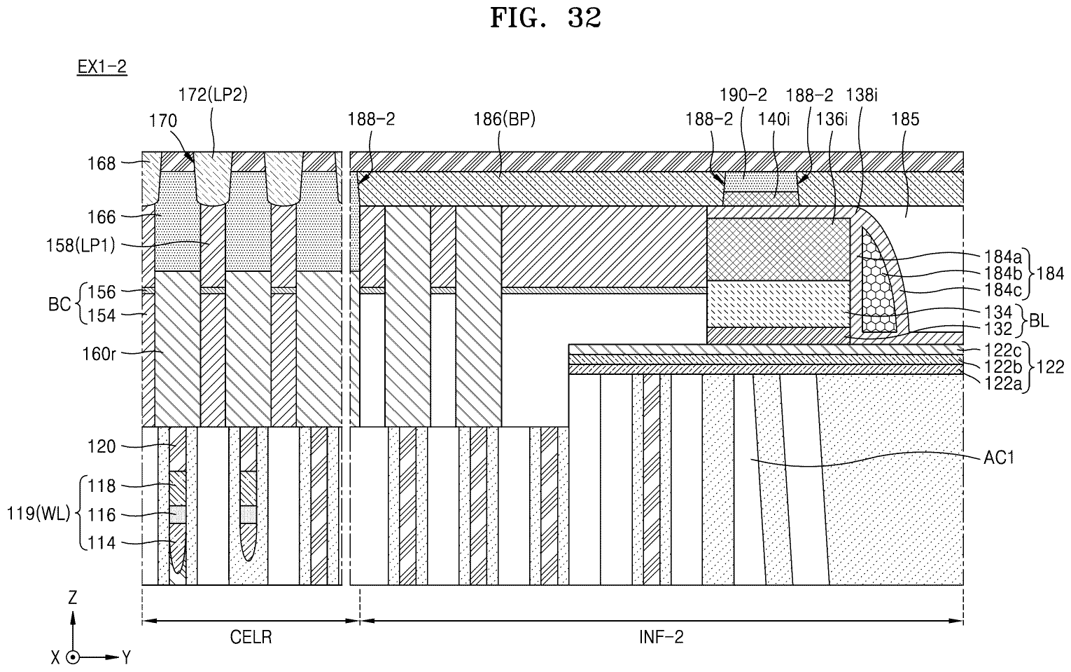

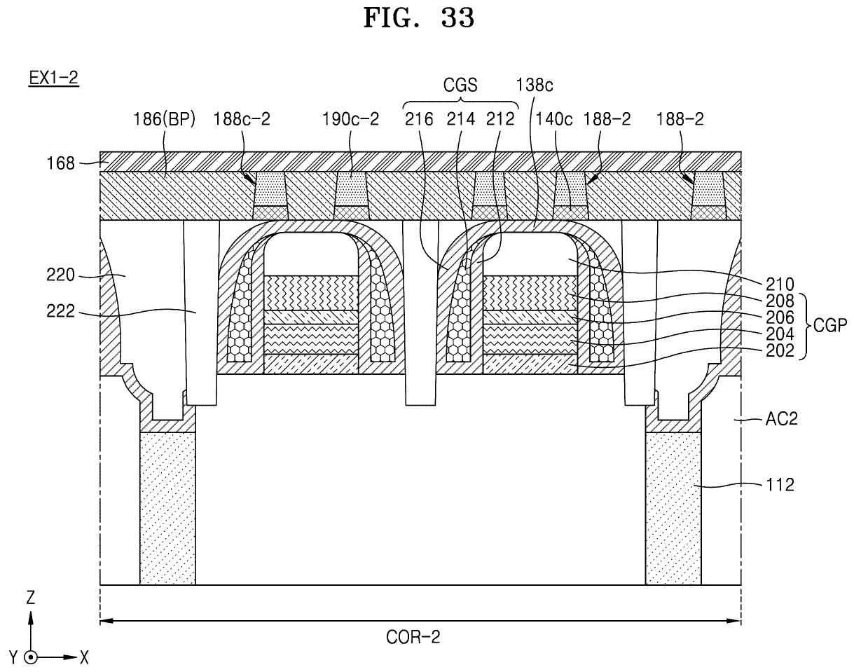

Specifically, FIGS. 31 and 32 are cross-sectional views showing the semiconductor device EX1-2 including the cell region CELR of FIGS. 3A and 4A, respectively, and the interface region INF-2 adjacent to the cell region CELR according to an embodiment. FIG. 33 is a cross-sectional view showing the core region COR-2 of the semiconductor device EX1-2 according to an embodiment.

The semiconductor device EX1-2 may be substantially the same as the semiconductor device EX1 of FIGS. 25 to 27, except that a method of forming an interface opening hole 188-2 and a core opening hole 188c-2 of the semiconductor device EX1-2 is different from that of the semiconductor device EX1. The descriptions given with reference to FIGS. 25 to 27 are briefly given or omitted when describing FIGS. 31 to 33.

Referring to FIGS. 31 and 32, a landing insulating layer 166 may be formed in the cell region CELR, surround the sidewalls of a plurality of first landing pads LP1, and cover the upper portions of the plurality of first landing pads LP1.

The interface opening hole 188-2 may be formed in the interface region INF-2. A third interface insulating capping material layer and an interface insulating material layer may be formed on a first interface insulating capping pattern 136ri and then photo-etched, to thereby form the interface opening hole 188-2.

The interface opening hole 188-2 may be formed inside insulating layers. In some embodiments, the lower surface of the interface opening hole 188-2 may be located on the upper surface of the first interface insulating capping pattern 136ri. A third interface insulating capping pattern 140i and an interface insulating layer 190-2 may be formed on the first interface insulating capping pattern 136ri.

The interface insulating layer 190-2 includes a silicon oxide layer. The landing insulating layer 166 of the cell region CELR and the interface insulating layer 190-2 of the interface region INF-2 may be formed during the same process.

Landing opening holes 170 are formed inside the landing insulating layer 166 in the cell region CELR. Second landing pads LP2 connected to the first landing pads LP1 are formed in the landing opening holes 170. Each of the second landing pads LP2 may include an upper conductive pattern 172. A conductive layer 186-1 constituting a buried pattern BP may be formed inside the interface opening hole 188-2. The second landing pad LP2 and the buried pattern BP may be formed during the same process.

A stopper insulating layer 168 may be formed on the second landing pad LP2 and the landing insulating layer 166 in the cell region CELR. The stopper insulating layer 168 may be formed on the interface insulating layer 190-2 and the buried pattern BP in the interface region INF-2.

Referring to FIG. 33, the core opening hole 188c-2 may be formed in the core region COR-2. A third core insulating capping material layer and a core insulating material layer may be formed on the second core insulating capping pattern 138c and the core interlayer insulating layer 220 and then photo-etched, to thereby form the core opening hole 188c-2.

The core opening hole 188c-2 may be formed inside insulating layers. In some embodiments, the lower surface of the core opening hole 188c-2 may be located on the upper surface of the core interlayer insulating layer 220. A third core insulating capping pattern 140c and a core insulating layer 190c-2 may be formed on the core interlayer insulating layer 220. A core buried pattern BP may be formed inside the core opening hole 188c-2. The core buried pattern BP may include a conductive layer 186-1.

The core insulating layer 190c-2 includes a silicon oxide layer. The landing insulating layer 166 of the cell region CELR and the core insulating layer 190c-2 of the core region COR-2 may be formed during the same process.

A stopper insulating layer 168 may be formed on the core region COR-2. The stopper insulating layer 168 may be formed on the core insulating layer 190c-2 and the buried pattern BP in the core region COR-2.

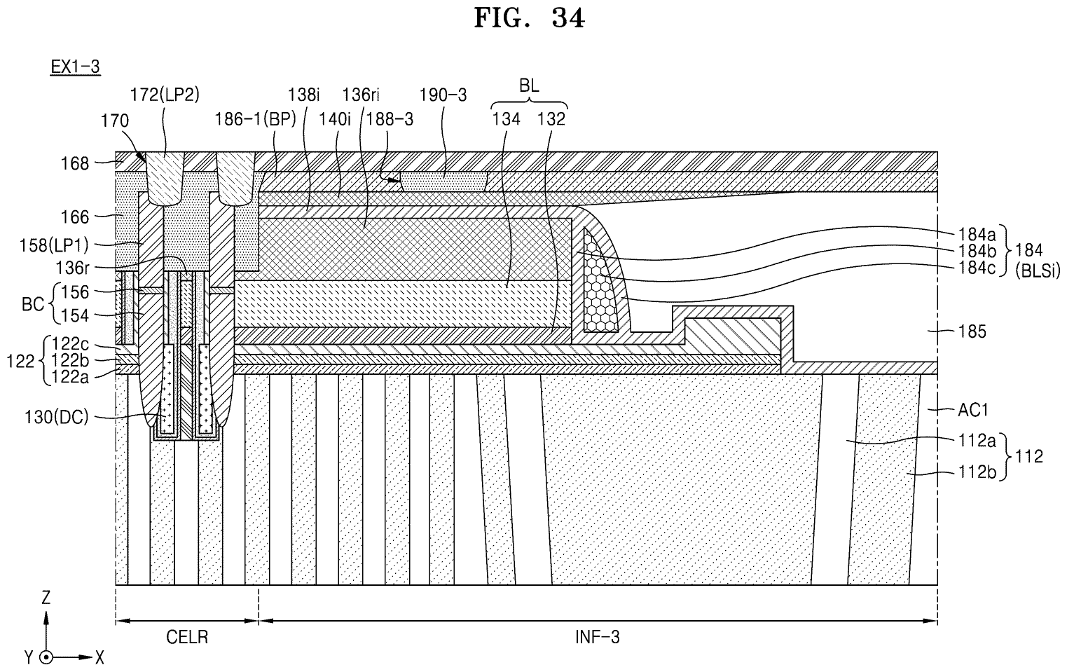

FIGS. 34 to 36 are cross-sectional views illustrating a semiconductor device EX1-3 including a cell region CELR, an interface region INF-3, and a core region COR-3, according to an embodiment.

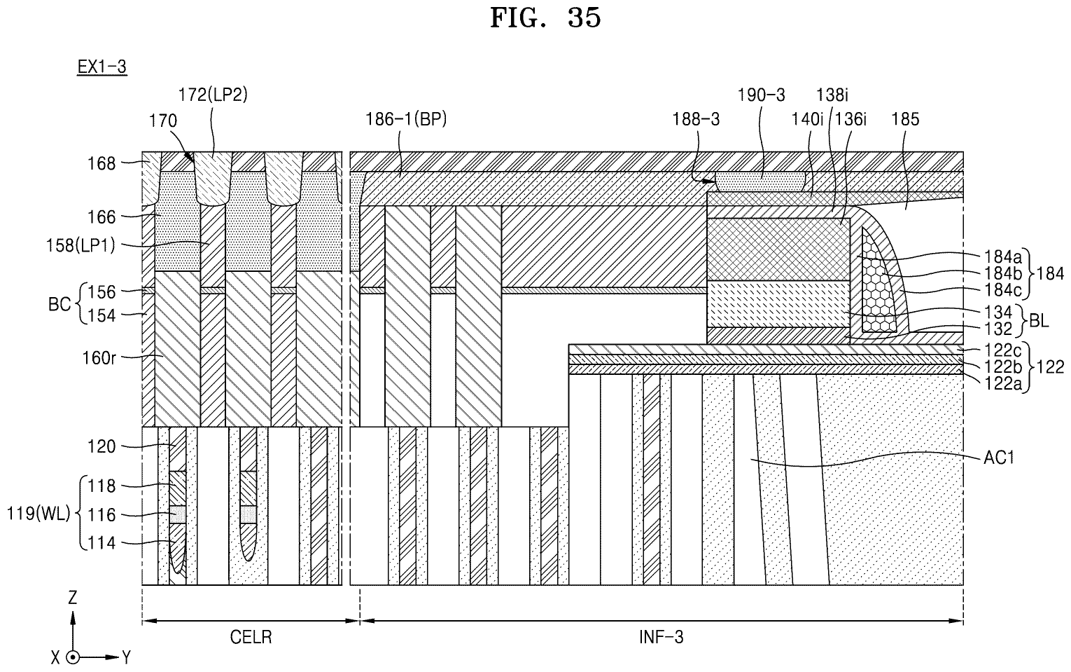

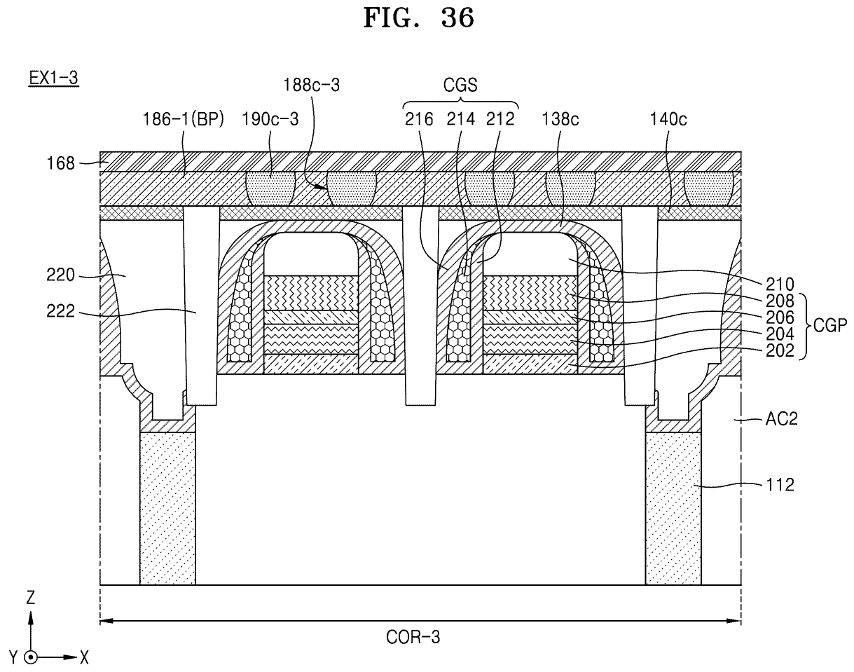

Specifically, FIGS. 34 and 35 are cross-sectional views showing the semiconductor device EX1-3 including the cell region CELR of FIGS. 3A and 4A, respectively, and the interface region INF-3 adjacent to the cell region CELR according to an embodiment. FIG. 36 is a cross-sectional view showing the core region COR-3 of the semiconductor device EX1-3 according to an embodiment.

The semiconductor device EX1-3 may be substantially the same as the semiconductor device EX1-2 of FIGS. 31 to 33, except that the structures of an interface opening hole 188-3 and a core opening hole 188c-3 of the semiconductor device EX1-3 are different from those of the semiconductor device EX1-2. The descriptions given with reference to FIGS. 31 to 33 are briefly given or omitted when describing FIGS. 34 to 36.

Referring to FIGS. 34 and 35, a landing insulating layer 166 may be formed in the cell region CELR, surround the sidewalls of a plurality of first landing pads LP1, and cover the upper portions of the plurality of first landing pads LP1.

The interface opening hole 188-3 may be formed in the interface region INF-3. An interface insulating material layer may be formed on a third interface insulating capping pattern 140i and then photo-etched, to thereby form the interface opening hole 188-3. The interface opening hole 188-3 may be formed inside an insulating layer. In some embodiments, the lower surface of the interface opening hole 188-3 may be located on the upper surface of the third interface insulating capping pattern 140i.

An interface insulating layer 190-3 may be formed on the third interface insulating capping pattern 140i. The interface insulating layer 190-3 may include a different material from the landing insulating layer 166 of the cell region CELR. For example, the interface insulating layer 190-3 may include a silicon nitride layer.

Landing opening holes 170 are formed inside the landing insulating layer 166 in the cell region CELR. Second landing pads LP2 connected to the first landing pads LP1 are formed in the landing opening holes 170. Each of the second landing pads LP2 may include an upper conductive pattern 172. A conductive layer 186-1 constituting a buried pattern BP may be formed inside the interface opening hole 188-3. The second landing pad LP2 and the buried pattern BP may be formed during the same process.

A stopper insulating layer 168 may be formed on the second landing pad LP2 and the landing insulating layer 166 in the cell region CELR. The stopper insulating layer 168 may be formed on the interface insulating layer 190-3 and the buried pattern BP in the interface region INF-3.

Referring to FIG. 36, the core opening hole 188c-3 may be formed in the core region COR-3. A core insulating material layer may be formed on the second core insulating capping pattern 138c and the core interlayer insulating layer 220 and then photo-etched, to thereby form the core opening hole 188c-3.

The core opening hole 188c-3 may be formed inside insulating layers. In some embodiments, the lower surface of the core opening hole 188c-3 may be located on the upper surface of the third core insulating capping pattern 140c. A core insulating layer 190c-3 may be formed on the core interlayer insulating layer 220. A core buried pattern BP may be formed inside the core opening hole 188c-3. The core buried pattern BP may include a conductive layer 186-1.

The core insulating layer 190c-3 includes a silicon nitride layer. A stopper insulating layer 168 may be formed on the core region COR-3. The stopper insulating layer 168 may be formed on the core insulating layer 190c-3 and the buried pattern BP in the core region COR-3.

While the inventive concept has been particularly shown and described with reference to embodiments thereof. it will be understood that various changes in form and details may be made therein without departing from the spirit and scope of the following claims.

What is claimed is:

1. A semiconductor device comprising:
a semiconductor substrate;
a plurality of contact plugs spaced apart from each other on the semiconductor substrate;
a plurality of first landing pads spaced apart from each other on the plurality of contact plugs;
a landing insulating layer surrounding upper sidewalls of the plurality of first landing pads and covering upper portions of the plurality of first landing pads;
a stopper insulating layer disposed on the landing insulating layer; and
a plurality of second landing pads spaced apart from each other on the plurality of first landing pads, passing through the stopper insulating layer, and buried in landing opening holes formed in the landing insulating layer, the plurality of second landing pads being electrically and respectively connected to the plurality of first landing pads.

2. The semiconductor device of claim 1, further comprising
a plurality of conductive patterns formed on the semiconductor substrate between the plurality of contact plugs.

3. The semiconductor device of claim 1,
wherein the landing insulating layer is placed between a first horizontal line located at a first vertical distance from an upper surface of each of the plurality of first landing pads in a direction toward the plurality of contact plugs and a second horizontal line located at a second vertical distance from the upper surface of each of the plurality of first landing pads in a direction toward the stopper insulating layer.

4. The semiconductor device of claim 1,
wherein the landing insulating layer comprises a silicon oxide film or a silicon oxycarbide (SiOC) film, which has lower permittivity than a silicon nitride layer.

5. The semiconductor device of claim 1,
wherein a width of a lower surface of each of the plurality of first landing pads is equal to a width of an upper surface of a corresponding one of the plurality of contact plugs.

6. The semiconductor device of claim 1, further comprising:
a landing spacer on one sidewall of a corresponding first landing pad of the plurality of first landing pads,
wherein a width of a lower surface of the corresponding first landing pad is less than a width of an upper surface of a corresponding contact plug of the plurality of contact plugs, and
wherein the corresponding first landing pad vertically overlaps the corresponding contact plug.

7. The semiconductor device of claim 1,
wherein each of the plurality of first landing pads comprises:
a first sub-landing pad disposed on a corresponding contact plug of the plurality of contact plugs; and
a second sub-landing pad disposed on the first sub-landing pad, and
wherein a width of a lower surface of the second sub-landing pad is less than a width of an upper surface of the first sub-landing pad,

8. The semiconductor device of claim 7, further comprising: a second sub-landing spacer on one sidewall of the second sub-landing pad.

9. The semiconductor device of claim 1,
wherein each of the plurality of first landing pads comprises:
a first sub-landing pad disposed on a corresponding one of the plurality of contact plugs; and
a second sub-landing pad disposed on the first sub-landing pad, and
wherein a width of an upper surface of the first sub-landing pad is less than a width of a lower surface of the second sub-landing pad.

10. The semiconductor device of claim 7, further comprising:
a landing spacer on one sidewall of each of the plurality of first landing pads,
wherein a width of the first sub-landing pad is less than a width of the corresponding contact plug, and
wherein the landing spacer includes a first sub-landing spacer and a second sub-landing spacer which are respectively arranged on one sidewall of the first sub-landing pad and one sidewall of the second sub-landing pad.

11. A semiconductor device comprising:
a semiconductor substrate;
a plurality of contact plugs spaced apart from each other on the semiconductor substrate in a first horizontal direction and a second horizontal direction perpendicular to the first horizontal direction;
a plurality of first landing pads spaced apart from each other on the plurality of contact plugs in the first horizontal direction and the second horizontal direction;
a plurality of fence insulating layers arranged on the semiconductor substrate, wherein each of the fence insulating layers extends lengthwise in the first horizontal direction and the plurality of fence insulating layers are spaced apart from each other in the second horizontal direction;
a landing insulating layer disposed on the plurality of fence insulating layers, surrounding upper sidewalls of the plurality of first landing pads, and covering upper portions of the plurality of first landing pads;
a stopper insulating layer disposed on the landing insulating layer; and
a plurality of second landing pads spaced apart from each other on the plurality of first landing pads in the first horizontal direction and the second horizontal direction, passing through the stopper insulating layer, and buried in landing opening holes formed in the landing insulating layer, the plurality of second landing pads being electrically and respectively connected to the plurality of first landing pads.

12. The semiconductor device of claim 11, further comprising
a plurality of conductive patterns arranged between the plurality of contact plugs in the first horizontal direction on the semiconductor substrate and
a spacer structure disposed on one sidewall of the plurality of conductive patterns.

13. The semiconductor device of claim 11,
wherein each of the plurality of fence insulating layers comprises a different material from the landing insulating layer.

14. The semiconductor device of claim 11,
wherein the fence insulating layers comprise a silicon nitride film, and
wherein the landing insulating layer comprises a silicon oxide film or a silicon oxycarbide (SiOC) film, which has lower permittivity than the silicon nitride film.

15. The semiconductor device of claim 11,
wherein each of the plurality of second landing pads is horizontally shifted, by a first offset distance, from a corresponding one of the plurality of first landing pads in a first horizontal direction.

16. The semiconductor device of claim 11,
wherein each of the plurality of second landing pads and a corresponding first landing pad of the plurality of first landing pads are vertically aligned with each other.

17. A semiconductor device comprising a semiconductor substrate comprising a cell region and an interface region surrounding the cell region,
wherein the cell region comprises:
a plurality of first contact plugs spaced apart from each other on the semiconductor substrate;
a plurality of first landing pads arranged on the plurality of first contact plugs;
a landing insulating layer surrounding upper sidewalls of the plurality of first landing pads and covering upper portions of the plurality of first landing pads;
a stopper insulating layer disposed on the landing insulating layer; and
a plurality of second landing pads spaced apart from each other on the plurality of first landing pads, passing through the stopper insulating layer, and buried in landing opening holes formed in the landing insulating layer, the plurality of second landing pads being electrically and respectively connected to the plurality of first landing pads,
wherein the interface region comprises:
a plurality of second contact plugs;
a plurality of interface insulating capping patterns formed above the plurality of second contact plugs;
a plurality of buried patterns formed on the interface insulating capping patterns; and
an interface insulating layer insulating the plurality of buried patterns from each other on the interface insulating capping patterns.

18. The semiconductor device of claim 17,
wherein the interface insulating layer is buried in the plurality of interface insulating capping patterns and an interface opening hole formed in the plurality of buried patterns.

19. The semiconductor device of claim 17,
wherein the plurality of buried patterns are buried in an interface opening hole inside the interface insulating layer formed on the plurality of interface insulating capping patterns.

20. The semiconductor device of claim 17,
wherein the semiconductor substrate further comprises a core region surrounding the interface region, and
wherein the core region comprises a plurality of core insulating capping patterns formed on a core gate pattern, a plurality of core buried patterns formed on the core insulating capping patterns, and a core insulating layer insulating the plurality of core buried patterns from each other on the plurality of core insulating capping patterns.
